(19) United States
(12) Patent Application Publication
(10) Pub. No.: US 2026/0113967 A1
(43) Pub. Date: Apr. 23, 2026

(54) SEMICONDUCTOR DEVICE INCLUDING ISOLATION STRUCTURE WITH CONVEX TOP SURFACE AND METHOD FOR MANUFACTURING THE SAME

(71) Applicant: TAIWAN SEMICONDUCTOR MANUFACTURING COMPANY, LTD., Hsinchu (TW)

(72) Inventors: Pin-Jung CHEN, Hsinchu (TW); Hong-Chih CHEN, Hsinchu (TW); Ta-Chun LIN, Hsinchu (TW); Wen-Che TSAI, Hsinchu (TW); Chun-Jun LIN, Hsinchu (TW); Kao-Ting LAI, Hsinchu (TW); Ming-Che CHEN, Hsinchu (TW)

(73) Assignee: TAIWAN SEMICONDUCTOR MANUFACTURING COMPANY, LTD., Hsinchu (TW)

(21) Appl. No.: 18/924,353

(22) Filed: Oct. 23, 2024

(51) Int. Cl. H01L 29/775; H01L 29/06; H01L 29/423; H01L 29/66; H01L 29/786

(52) U.S. Cl. CPC H10D 30/43; H10D 30/014; H10D 30/6735; H10D 30/6757; H10D 62/121; H10D 64/017

(57) ABSTRACT

A semiconductor device includes a substrate, a plurality of first channel features, a plurality of second channel features, and an isolation structure. The first channel features are spacedly disposed over the substrate in a first direction normal to the substrate. The second channel features are spacedly disposed over the substrate in the first direction and are spaced apart from the first channel features in a second direction transverse to the first direction. The isolation structure is disposed between the first channel features and the second channel features in the second direction and has a convex top surface.

### BACKGROUND

In fabrication of nanosheet transistors, such as gate-all-around (GAA) transistors, isolation elements (for example, but not limited to, shallow trench isolations (STIs)) are formed to prevent current leakage among different transistors. Improvement of physical structure of the isolation elements is urgently required to further reduce current leakage, so as to improve performance of the transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1D are flow diagrams illustrating a method for manufacturing a semiconductor device in accordance with some embodiments.

FIGS. 2 to 36 are schematic views illustrating some intermediate stages of the method as depicted in FIGS. 1A to 1D in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” “uppermost,” “lowermost,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain region(s)” may refer to a source or a drain, individually or collectively dependent upon the context.

In fabrication of nanosheet transistors, such as gate-all-around (GAA) transistors, isolation elements (for example, but not limited to, shallow trench isolations (STIs)) are formed to prevent current leakage among different transistors. In a current manufacturing method for a semiconductor device, the isolation elements are usually formed with a concave top surface, which may incur some problem in subsequent stages of the manufacturing method and in the semiconductor device manufactured thereby. For example, current leakage may occur among inner metal gate portions formed among semiconductor nanosheets, which serve as channel features of the GAA transistors, particularly among lower ones of the inner metal gate portions proximate to the isolation elements. In addition, an isolation feature, which is formed for dividing a metal gate structure into metal gate portions, may not terminate at the concave top surface of a corresponding one of the isolation elements, and thus current leakage may occur between the metal gate portions. Therefore, improvement of physical structure of the isolation elements is urgently required to further reduce current leakage, so as to improve performance of the transistors.

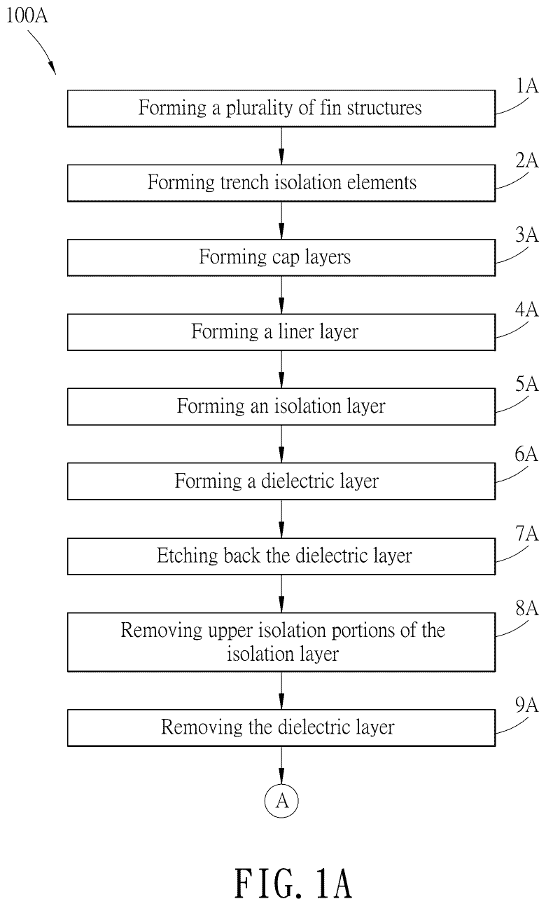

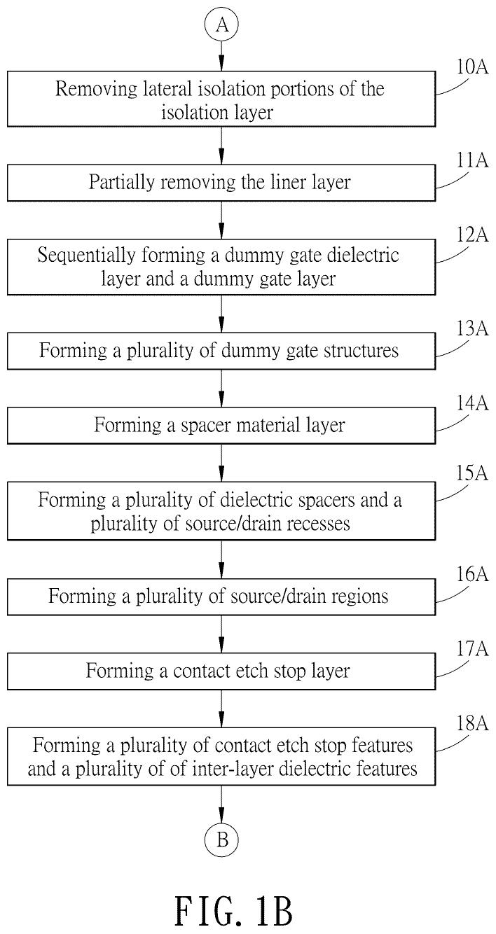

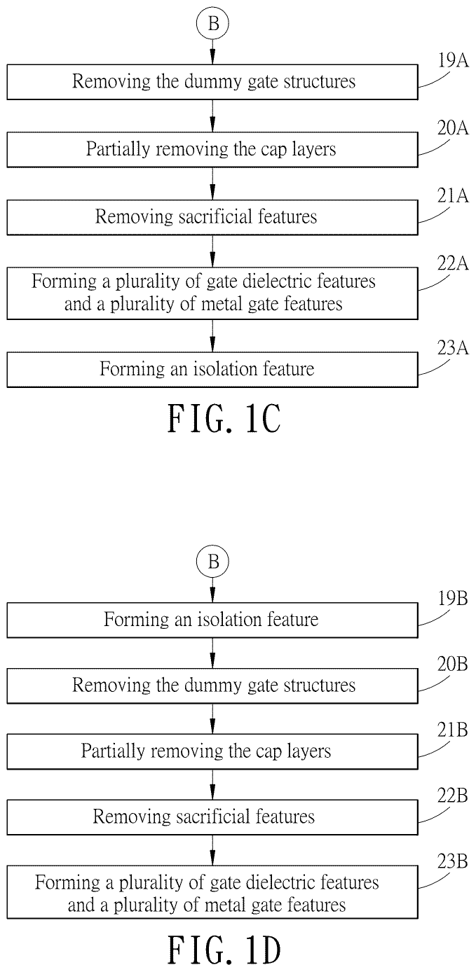

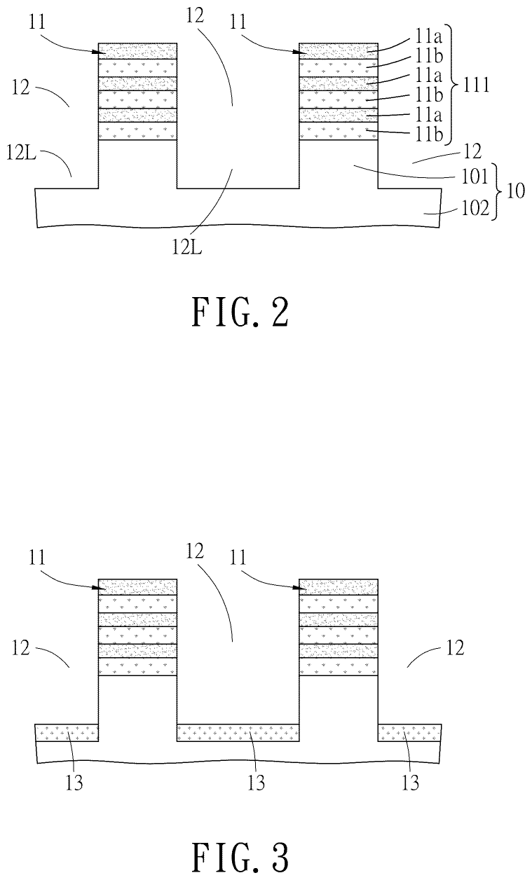

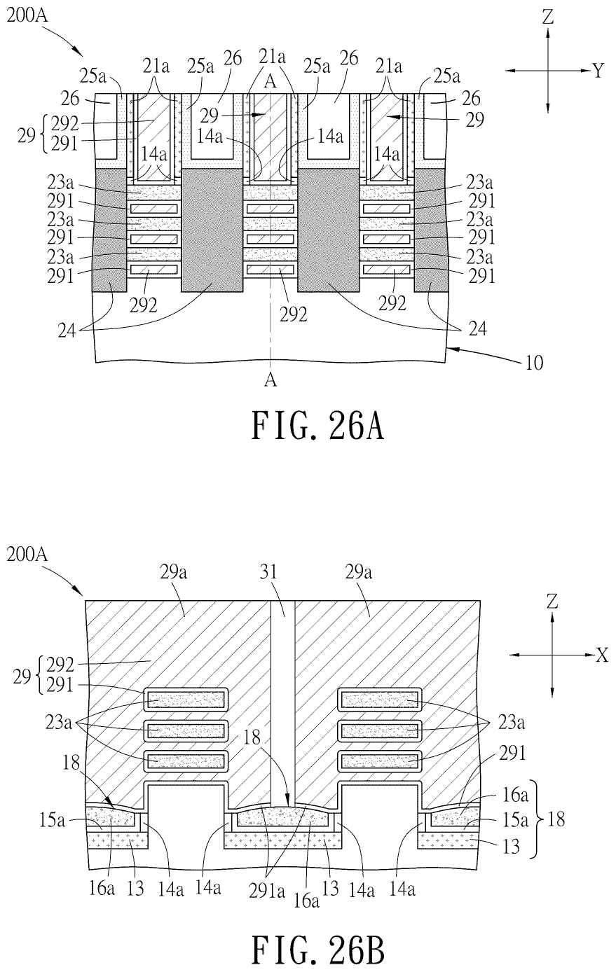

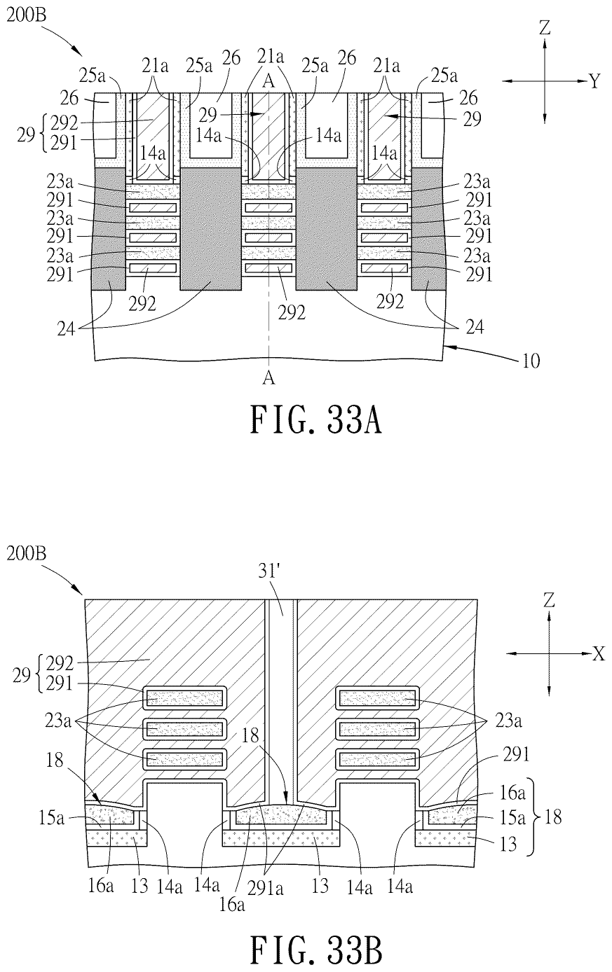

The present disclosure is directed to a semiconductor device including an isolation structure formed with a convex top surface and a method for manufacturing the same. FIGS. 1A to 1D are flow diagrams illustrating a method 100A for manufacturing a semiconductor device (for example, a semiconductor device 200A shown in FIGS. 26A and 26B or a semiconductor device 200B shown in FIGS. 33A and 33B) in accordance with some embodiments. FIGS. 2 to 33B illustrate schematic views of some intermediate stages of the method 100A. Some portions may be omitted in FIGS. 2 to 33B for the sake of brevity. Additional steps can be provided before, after or during the method 100A, and some of the steps described herein may be replaced by other steps or be eliminated.

Referring to FIG. 1A and the example illustrated in FIG. 2, the method 100 begins at step 1A, where a plurality of fin structures 11 are formed. Only two of the fin structures 11 are shown in FIG. 2. The fin structures 11 are formed by patterning a stack of semiconductor layers (not shown, hereinafter referred to as the stack) disposed on a substrate 10 and further etching back the substrate 10. The stack includes at least one first semiconductor layer including a first semiconductor material, and at least one second semiconductor layer that is disposed to alternate with the at least one first semiconductor layer and that includes a second semiconductor material different from the first semiconductor material. An uppermost one of the at least one first semiconductor layer is disposed over an uppermost one of the at least one second semiconductor layer such that an uppermost one of semiconductor layers in the stack is the uppermost one of the at least one of the first semiconductor layer. The first and second semiconductor materials have different etch selectivity and/or oxidation rates. In some embodiments, the first semiconductor material may be the same material as that of the substrate 10. The at least one first semiconductor layer and the at least one second semiconductor layer may be intrinsic or doped with a p-type dopant or an n-type dopant. In some embodiments, the first semiconductor material is silicon, and the second semiconductor material is silicon germanium (SiGe). Other materials suitable for the at least one first semiconductor layer and the at least one second semiconductor layer are within the contemplated scope of the disclosure. In some embodiments, the stack has a plurality of the first semiconductor layers and a plurality of the second semiconductor layers. The numbers of the first and second semiconductor layers in the stack are determined according to application requirements.

In some embodiments, the substrate 10 may be, for example, but not limited to, a silicon-on-insulator (SOI) substrate, a germanium-on-insulator (GOI) substrate, a bulk semiconductor substrate, or the like. The substrate 10 may have multiple layers. The substrate 10 may include, for example, elemental semiconductor materials, such as crystalline silicon, diamond, or germanium; compound semiconductor materials, such as silicon carbide, gallium arsenic, indium arsenide, gallium phosphide, indium arsenide, indium phosphide, or indium antimonide; alloy semiconductor materials, such as silicon germanium, silicon germanium carbide, gallium arsenic phosphide, aluminum gallium arsenide, or gallium indium phosphide; or combinations thereof. The substrate 10 may be intrinsic or doped with a dopant or different dopants. Other materials suitable for the substrate 10 are within the contemplated scope of the disclosure. In some embodiments, the substrate 10 is a bulk silicon substrate.

Each of the first semiconductor layers and the second semiconductor layers in the stack may be formed on the substrate 10 by a suitable fabrication technique, for example, but not limited to, chemical vapor deposition (CVD), plasma-enhanced CVD (PECVD), molecular-beam epitaxy (MBE), vapor-phase epitaxy (VPE), physical vapor deposition (PVD), atomic layer deposition (ALD), plasma-enhanced ALD (PEALD), or molecular-beam deposition (MBD). Other suitable techniques for forming the first semiconductor layers and the second semiconductor layers are within the contemplated scope of the disclosure.

The stack and the substrate 10 are patterned to form the fin structures 11 by removing portions of the stack and portions of the substrate 10 through a patterned mask layer (not shown) disposed on the stack. In some embodiments, the patterned mask layer may include, for example, but not limited to, a dielectric material, such as a nitride (e.g., silicon nitride), an oxide (e.g., silicon oxide), or a combination thereof. Other materials suitable for the patterned mask layer are within the contemplated scope of the disclosure. The patterning of the stack and the substrate 10 may be performed using any suitable etching process, for example, but not limited to, a dry etching process, a wet etching process, or a reactive ion etching (RIE) process. Other suitable techniques for patterning the stack and the substrate 10 are within the contemplated scope of the disclosure. In some embodiments, the etching process may be an anisotropic etching process.

Trenches 12 are formed to separate the fin structures 11 from one another. Each of the fin structures 11 includes a nanosheet stack 111 formed from patterning of the stack, and a substrate segment 101 (an upper substrate portion) formed from patterning of the substrate 10. The substrate segment 101 is disposed on a residual substrate segment 102 (a lower substrate portion). In some embodiments, the nanosheet stack 111 includes at least one first nanosheet 11a and at least one second nanosheet 11b alternating with the at least one first nanosheet 11a. In some embodiments, the nanosheet stack 111 includes a plurality of the first nanosheets 11a and a plurality of the second nanosheets 11b. The first nanosheets 11a are formed from patterning of the first semiconductor layers in the stack, and the second nanosheets 11b are formed from patterning of the second semiconductor layers in the stack.

Referring to FIG. 1A and the example illustrated in FIG. 3, the method 100 proceeds to step 2A, where trench isolation elements 13 are formed to fill lower portions 12L (see FIG. 2) of the trenches 12, respectively. To form the trench isolation elements 13, a first isolation material is filled in the trenches 12 by, for example, but not limited to, a deposition process, such as CVD, PECVD, FCVD (flowable CVD), or other suitable techniques. Thereafter, the first isolation material is planarized to remove an excess thereof such that an upper surface of the first isolation material is flush with upper surfaces of the fin structures 11. The planarization process may be a chemical mechanical planarization (CMP) process, other suitable techniques, or combinations thereof. Thereafter, the first isolation material is etched back to form the trench isolation elements 13 in the lower portions 12L of the trenches 12 using, for example, but not limited to, a dry etching process. Each of the trench isolation elements 13 has a height lower than that of the substrate segment 101 of each of the fin structures 11. The trench isolation elements 13 may serve as shallow trench isolation (STI) elements to alternate with the fin structures 11. The trench isolation elements 13 may include a dielectric material, for example, but not limited to, silicon oxide, silicon nitride, silicon carbonitride, silicon oxynitride, silicon carboxynitride, silicon carboxide, hafnium oxide, zirconium oxide, lanthanum oxide, aluminum oxide, or combinations thereof. Other materials and processes suitable for forming the trench isolation elements 13 are within the contemplated scope of the disclosure.

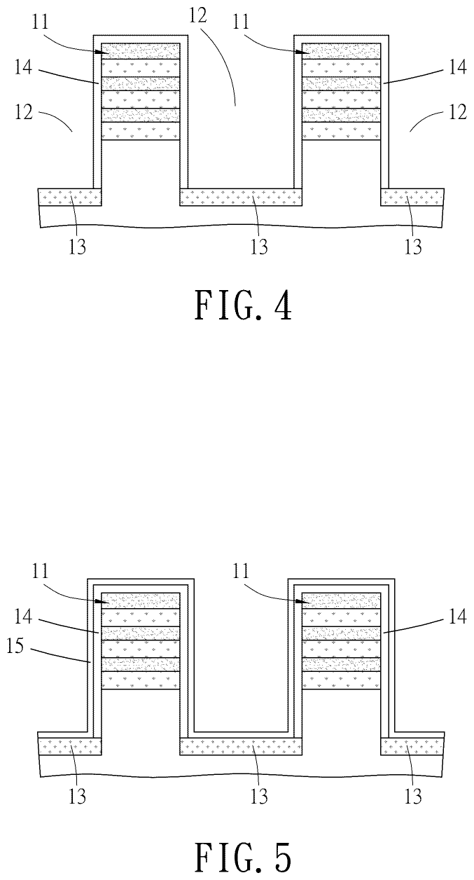

Referring to FIG. 1A and the example illustrated in FIG. 4, the method 100 proceeds to step 3A, where cap layers 14 are formed. The cap layers 14 are formed on the trench isolation elements 13 to respectively cover the fin structures 11. Two adjacent ones of the cap layers 14 are spaced apart from each other by a corresponding one of the trenches 12. The cap layers 14 may be formed by a suitable selective deposition technique such as selective CVD, selective ALD, or the like, or combinations thereof, and may include a semiconductor material (for example, but not limited to, silicon). Other suitable techniques and materials for forming the cap layers 14 are within the contemplated scope of the disclosure. In some embodiments, the cap layers 14 may be made of the same material as that of the first nanosheets 11a and/or the substrate 10.

Referring to FIG. 1A and the example illustrated in FIG. 5, the method 100 proceeds to step 4A, where a liner layer 15 is formed. In some embodiments, the liner layer 15 may be formed by conformally depositing a dielectric layer to cover the cap layers 14 and the trench isolation elements 13. In some embodiments, the dielectric layer for forming the liner layer 15 may be formed using a suitable fabrication technique such as ALD, CVD, PVD, PECVD, or the like, or combinations thereof. In some embodiments, the dielectric layer for forming the liner layer 15 includes a dielectric oxide material (for example, but not limited to, silicon oxide). Other materials and processes suitable for forming the liner layer 15 are within the contemplated scope of the disclosure.

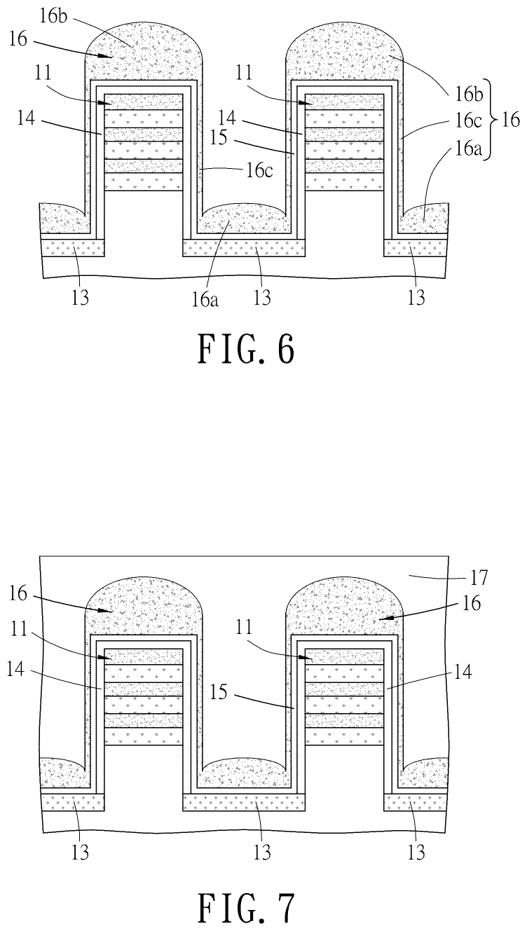

Referring to FIG. 1A and the example illustrated in FIG. 6, the method 100 proceeds to step 5A, where an isolation layer 16 is formed. The isolation layer 16 is formed to cover the liner layer 15. The isolation layer 16 includes a plurality of lower isolation portions 16a respectively disposed over the trench isolation elements 13, a plurality of upper isolation portions 16b respectively disposed over the fin structures 11, and a plurality of lateral isolation portions 16c, each of which interconnects a corresponding one of the lower isolation portions 16a and a corresponding one of the upper isolation portions 16b and each of which laterally covers the liner layer 15. Each of the lower isolation portions 16a and the upper isolation portions 16b is formed with a convex top surface. The isolation layer 16 is made of a second isolation material. In some embodiments, the second isolation material is different from the first isolation material for forming the trench isolation elements 13. In some embodiments, the second isolation material includes a dielectric material, for example, but not limited to, silicon oxide, silicon nitride, silicon carbonitride, silicon oxynitride, silicon carboxynitride, silicon carboxide, hafnium oxide, zirconium oxide, lanthanum oxide, aluminum oxide, or combinations thereof. In some embodiments, the isolation layer 16 may be formed using a suitable deposition process, for example, but not limited to, ALD, CVD, PEALD, PECVD, or the like. Other dielectric materials and processes suitable for forming the isolation layer 16 are within the contemplated scope of the disclosure. In some embodiments, the deposition process may be performed using a precursor gas, which includes, for example, but not limited to, silane (SiH₄), disilane (Si₂H₆), hydrogen (H₂) gas, nitrogen (N₂) gas, ammonia (NH₃), dichlorosilane (H₂SiCl₂), hexachlorodisilane (Si₂Cl₆), or combinations thereof. Other precursor gases suitable for forming the isolation layer 16 are within the contemplated scope of the disclosure. In some embodiments, the precursor gas may be introduced together with a carrier gas into a chamber for forming the isolation layer 16. In some embodiments, the carrier gas includes, for example, but not limited to, argon (Ar) gas, helium (He) gas, or other inert gases. In some embodiments, the precursor gas has a flow rate ranging from about 1.5 sccm to about 4600 sccm. In some embodiments, the deposition process may be performed at a plasma power ranging from about 50 W to about 2200 W. In some embodiments, the deposition process may be performed at a pressure ranging from about 0.4 torr to about 15 torr. In some embodiments, the deposition process may be performed for a process time ranging from about 800 sec to about 2880 sec. If the flow rate of the precursor gas is lower than 1.5 sccm, the plasma power is lower than 50 W, and/or the pressure is lower than 0.4 torr, the isolation layer 16 may not fully cover the liner layer 15. If the flow rate of the precursor gas is higher 4600 sccm, the plasma power is higher than 2200 W, and/or the pressure is higher than 15 torr, two adjacent ones of the upper isolation portions 16b of the isolation layer 16 may be merged together. The process time may be adjusted according to the flow rate of the precursor gas, the plasma power, and/or the pressure.

Referring to FIG. 1A and the example illustrated in FIG. 7, the method 100 proceeds to step 6A, where a dielectric layer 17 is formed. The dielectric layer 17 is formed to cover the isolation layer 16. In some embodiments, the dielectric layer 17 may include, for example, but not limited to, a bottom anti-reflective coating (BARC). Other dielectric materials suitable for the dielectric layer 17 are within the contemplated scope of the disclosure. In some embodiments, the dielectric layer 17 may be formed using a suitable deposition process, for example, but not limited to, ALD, CVD, PEALD, PECVD, or the like. Other processes suitable for forming the dielectric layer 17 are within the contemplated scope of the disclosure.

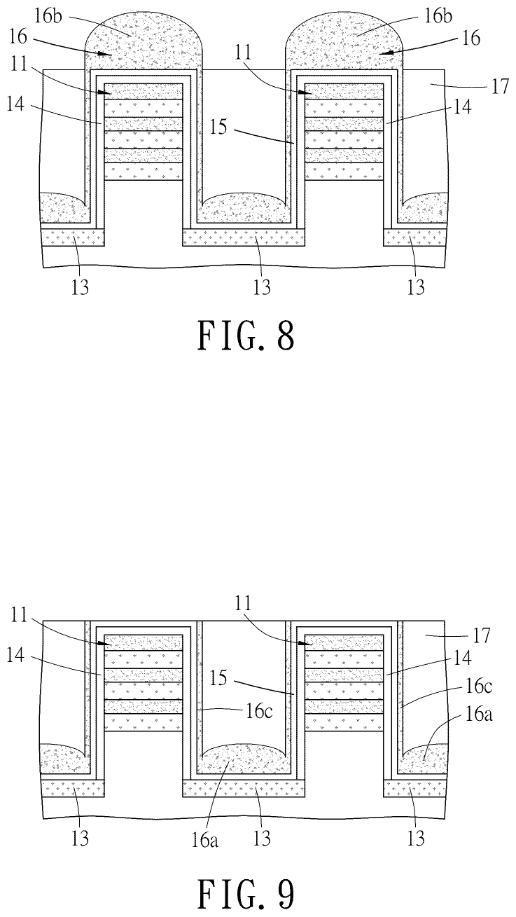

Referring to FIG. 1A and the example illustrated in FIG. 8, the method 100 proceeds to step 7A, where the dielectric layer 17 is etched back. The dielectric layer 17 is etched back using, for example, but not limited to, a selective dry etching process or a selective wet etching process, so as to expose the upper isolation portions 16b of the isolation layer 16 from the dielectric layer 17. Other processes suitable for etching back the dielectric layer 17 are within the contemplated scope of the disclosure.

Referring to FIG. 1A and the example illustrated in FIG. 9, the method 100 proceeds to step 8A, where the upper isolation portions 16b of the isolation layer 16 are removed. The upper isolation portions 16b of the isolation layer 16 of the structure shown in FIG. 8 are removed using, for example, but not limited to, a selective dry etching process or a selective wet etching process, so as to expose upper surfaces of the liner layer 15. Other processes suitable for removing the upper isolation portions 16b of the isolation layer 16 are within the contemplated scope of the disclosure. In some embodiments, after step 8A, an upper surface of the dielectric layer 17 is flush with the upper surfaces of the liner layer 15.

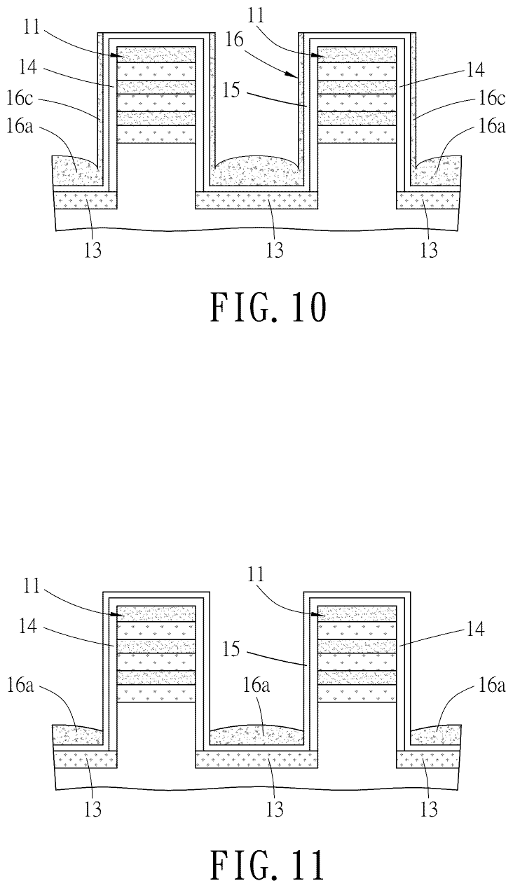

Referring to FIG. 1A and the example illustrated in FIG. 10, the method 100 proceeds to step 9A, where the dielectric layer 17 is removed. The dielectric layer 17 of the structure shown in FIG. 9 are removed using, for example, but not limited to, a selective dry etching process or a selective wet etching process. Other processes suitable for removing the dielectric layer 17 are within the contemplated scope of the disclosure.

Referring to FIG. 1B and the example illustrated in FIG. 11, the method 100 proceeds to step 10A, where the lateral isolation portions 16c of the isolation layer 16 are removed. The lateral isolation portions 16c of the isolation layer 16 of the structure shown in FIG. 10 are removed using, for example, but not limited to, a selective wet clean process or a selective dry etching process, so as to leave the lower isolation portions 16a on the liner layer 15. Other processes suitable for removing the lateral isolation portions 16c of the isolation layer 16 are within the contemplated scope of the disclosure. In some embodiments, an upper part of each of the lower isolation portions 16a may be removed when the lateral isolation portions 16c of the isolation layer 16 are fully removed. In some embodiments, the wet clean process is performed using an acid solution (for example, but not limited to, a phosphoric acid solution). In some embodiments, the acid solution has a concentration ranging from about 12% to about 63%. In some embodiments, the wet clean process is performed for a process time ranging from about 13 sec to about 155 sec. In some embodiments, the wet clean process is performed at a temperature ranging from about 85° C. to about 360° C. If the concentration of the acid solution is lower than 12%, acid included in the acid solution may be evaporated, and thus the wet clean process cannot be performed. If the temperature is lower than 85° C., the wet clean process cannot be performed. If the temperature is higher than 360° C., process stability of the wet clean process is not satisfactory. In some embodiments, the dry etching process is performed using an etching gas which includes, for example, but not limited to, hydrogen fluoride (HF) gas, hydrogen (H₂) gas, nitrogen (N₂) gas, oxygen (O₂) gas, or combinations thereof. In some embodiments, the etching gas may be used together with a carrier gas (for example, but not limited to, argon (Ar) gas, helium (He) gas, or other inert gases). In some embodiments, the dry etching process is performed at a temperature ranging from about 20° C. to about 55° C. In some embodiments, the dry etching process is performed at a plasma power ranging from about 80 W to about 3100 W. If the temperature is lower than 20° C. and/or the plasma power is lower than 80 W, the dry etching process cannot be performed. If the temperature is higher than 55° C. and/or the plasma power is higher than 3100 W, the dry etching process may be performed excessively. In some embodiments, the dry etching process is performed for a process time ranging from about 1.5 sec to about 95.0 sec.

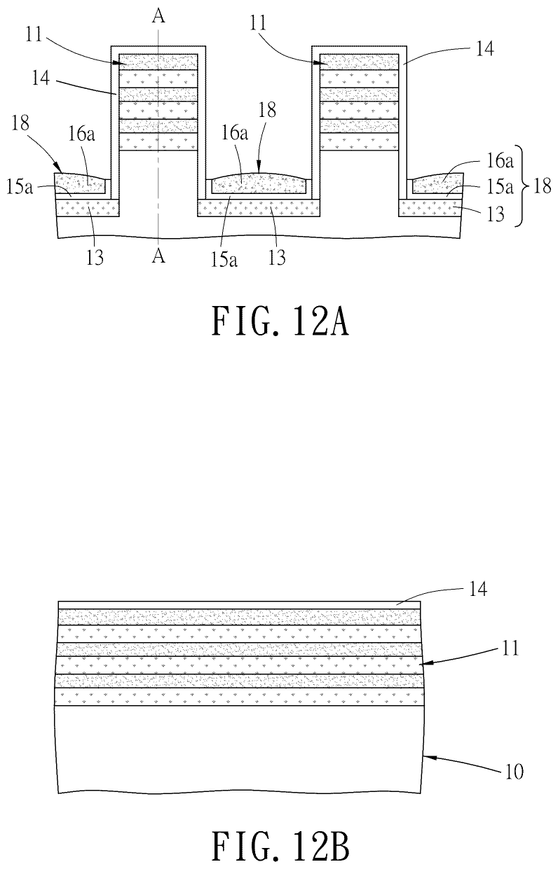

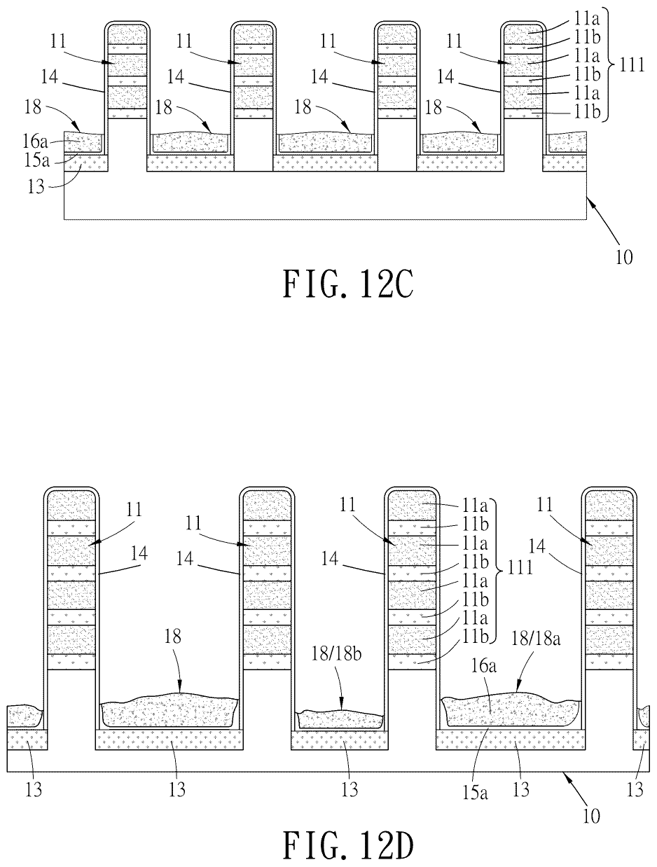

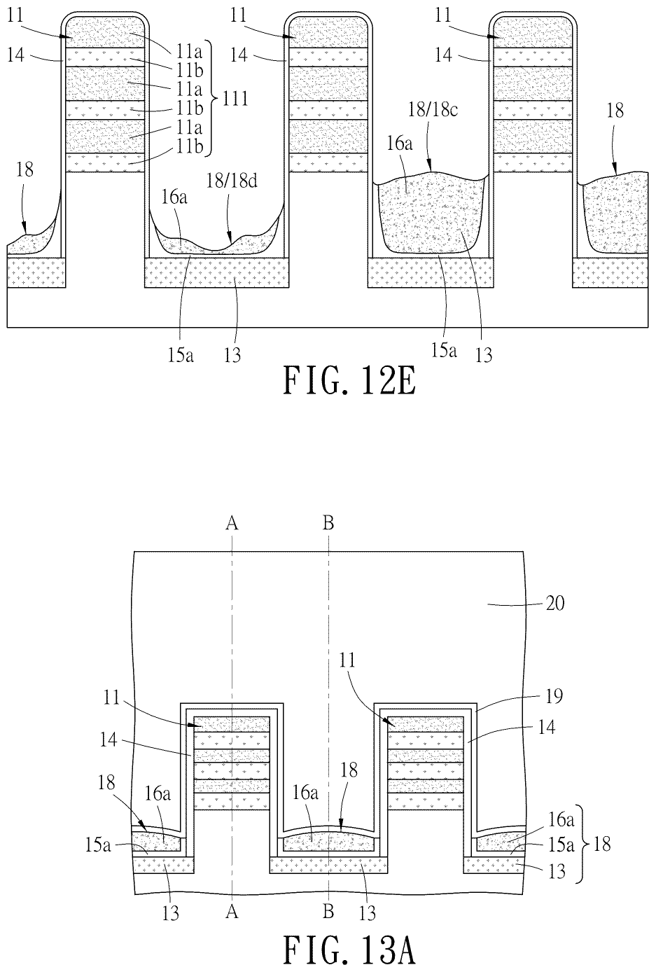

Referring to FIG. 1B and the examples illustrated in FIGS. 12A, 12B, and 12C, the method 100 proceeds to step 11A, where the liner layer 15 is partially removed. FIG. 12B is a schematic view taken along line A-A shown in FIG. 12A. Portions of the liner layer 15 exposed from the lower isolation portions 16a (see FIG. 11) are removed using, for example, but not limited to, a selective dry etching process or a selective wet etching process, so as to form a plurality of liners 15a. The liners 15a, the trench isolation elements 13, and the lower isolation portions 16a are collectively configured as a plurality of isolation structures 18. Each of the liners 15a includes a bottom liner portion disposed between a corresponding one of the lower isolation portions 16a and a corresponding one of the trench isolation elements 13, and a side liner portion extending from the bottom liner portion to laterally cover the corresponding one of the lower isolation portions 16a. The liners 15a are formed by etching the portions of the liner layer 15 exposed from the lower isolation portions 16a. The isolation structures 18 are disposed to alternate with the fin structures 11. Each of the isolation structures 18 is separated from a corresponding one of the fin structures 11 by a corresponding one of the cap layers 14. Each of the isolation structures 18 is formed with a convex top surface, and includes one of the trench isolation elements 13, a corresponding one of the liners 15a disposed on the one of the trench isolation elements 13, and a corresponding one of the lower isolation portions 16a (referred to as isolation portions 16a hereinafter) having the convex top surface.

Referring to the example illustrated in FIG. 12D, in some alternative embodiments, the isolation portions 16a of the isolation structures 18 of the structure obtained after step 11A may have different heights. The isolation structures 18 includes a first isolation structure 18a and a second isolation structure 18b. The isolation portion 16a of the first isolation structure 18a is formed with a convex top surface and has a first height, and the isolation portion 16a of the second isolation structure 18b is formed with a convex top surface and has a second height that is less than the first height. In some embodiments, the first height of the isolation portion 16a of the first isolation structure 18a is greater than the second height of the isolation portion 16a of the second isolation structure 18b by a value ranging from about 2 nm to about 20 nm. Processes for forming the structure shown in FIG. 12D are similar to those forming the structure shown in FIGS. 12A, 12B, and 12C, except that operation parameters for performing step 5A (i.e., formation of the isolation layer 16) and operation parameters for performing step 10A (i.e., removal of the lateral isolation portions 16C of the isolation layer 16) are different from those described above.

In the some alternative embodiments, the deposition process (for example, but not limited to, ALD, CVD, PEALD, PECVD, or the like) for forming the isolation layer 16 may be performed using a precursor gas (for example, but not limited to, silane, disilane, hydrogen gas, nitrogen gas, ammonia, dichlorosilane, hexachlorodisilane, or combinations thereof) with a flow rate ranging from about 0.5 sccm to about 3600 sccm and a carrier gas (for example, but not limited to, argon gas, helium gas, or other inert gases). The deposition process is conducted at a plasma power ranging from about 30 W to about 3600 W, at a pressure ranging from about 0.4 torr to about 15 torr, and for a process time ranging from about 450 sec to about 4300 sec. If the flow rate of the precursor gas is lower than 0.5 sccm, the plasma power is lower than 30 W, and/or the pressure is lower than 0.4 torr, the isolation layer 16 may not fully cover the liner layer 15. If the flow rate of the precursor gas is higher than 3600 sccm, the plasma power is higher than 3600 W, and/or the pressure is higher than 15 torr, two adjacent ones of the upper isolation portions 16b of the isolation layer 16 may be merged together. The process time may be adjusted according to the flow rate of the precursor gas, the plasma power, and/or the pressure.

The lateral isolation portions 16C of the isolation layer 16 may be removed using a wet clean process or a dry etching process. The wet clean process is performed using an acid solution (for example, but not limited to, a phosphorus acid solution) with a concentration ranging from about 12% to 63% at a temperature ranging from about 120° C. to about 360° C., and for a process time ranging from about 6.5 sec to about 85.0 sec. The dry etching process is performed using an etching gas (for example, but not limited to, hydrogen fluoride gas, hydrogen gas, nitrogen gas, oxygen gas, or combinations thereof) and a carrier gas (for example, but not limited to, argon gas, helium gas, or other inert gases) at a temperature ranging from about 20° C. to about 75° C., at a plasma power ranging from about 120 W to about 3500 W, and for a process time ranging from about 1.5 sec to about 65 sec. In the wet clean process, if the concentration of the acid solution is lower than 12%, acid included in the acid solution may be evaporated, and thus the wet clean process cannot be performed. If the temperature is lower than 120° C., the wet clean process cannot be performed. If the temperature is higher than 360° C., process stability of the wet clean process is not satisfactory. In the dry etching process, if the temperature is lower than 20° C. and/or the plasma power is lower than 120 W, the dry etching process cannot be performed. If the temperature is higher than 75° C. and/or the plasma power is higher than 3500 W, the dry etching process may be performed excessively.

Referring to the example illustrated in FIG. 12E, in some further alternative embodiments, the isolation portions 16a of the isolation structures 18 of the structure obtained after step 11A may have convex or concave top surfaces and have different heights. The isolation structures 18 includes a first isolation structure 18c and a second isolation structure 18d. The isolation portion 16a of the first isolation structure 18c is formed with a convex top surface and has a first height, and the isolation portion 16a of the second isolation structure 18d is formed with a concave top surface and has a second height that is less than the first height of the isolation portion 16a of the first isolation structure 18c. In some embodiments, the first height of the isolation portion 16a of the first isolation structure 18c is greater than the second height of the isolation portion 16a of the second isolation structure 18d by a value ranging from about 2 nm to about 20 nm. Processes for forming the structure shown in FIG. 12E are similar to those for forming the structure shown in FIGS. 12A, 12B, and 12C, except that operation parameters for performing step 5A (i.e., formation of the isolation layer 16) and operation parameters for performing step 10A (i.e., removal of the lateral isolation portions 16C of the isolation layer 16) are different from those described above.

In the some further alternative embodiments, the deposition process (for example, but not limited to, ALD, CVD, PEALD, PECVD, or the like) for forming the isolation layer 16 may be performed using a precursor gas (for example, but not limited to, silane, disilane, hydrogen gas, nitrogen gas, ammonia, dichlorosilane, hexachlorodisilane, or combinations thereof) with a flow rate ranging from about 5 sccm to about 6000 sccm and a carrier gas (for example, but not limited to, argon gas, helium gas, or other inert gases). The deposition process is conducted at a plasma power ranging from about 30 W to about 3600 W, at a pressure ranging from about 0.6 torr to about 20 torr, and for a process time ranging from about 450 sec to about 4300 sec. If the flow rate of the precursor gas is lower than 5 sccm, the plasma power is lower than 30 W, and/or the pressure is lower than 0.6 torr, the isolation layer 16 may not fully cover the liner layer 15. If the flow rate of the precursor gas is higher 6000 sccm, the plasma power is higher than 3600 W, and/or the pressure is higher than 20 torr, two adjacent ones of the upper isolation portions 16b of the isolation layer 16 may be merged together. The process time may be adjusted according to the flow rate of the precursor gas, the plasma power, and/or the pressure.

Removal of the lateral isolation portions 16C of the isolation layer 16 may be performed using a wet clean process or a dry etching process. The wet clean process is performed using an acid solution (for example, but not limited to, a phosphorus acid solution) with a concentration ranging from about 12% to 63% at a temperature ranging from about 200° C. to about 360° C., and for a process time ranging from about 20 sec to about 150 sec. The dry etching process is performed using an etching gas (for example, but not limited to, hydrogen fluoride gas, hydrogen gas, nitrogen gas, oxygen gas, or combinations thereof) and a carrier gas (for example, but not limited to, argon gas, helium gas, or other inert gases) at a temperature ranging from about 20° C. to about 75° C., at a plasma power ranging from about 120 W to about 3500 W, and for a process time ranging from about 3.5 sec to about 85 sec. In the wet clean process, if the concentration of the acid solution is lower than 12%, acid included in the acid solution may be evaporated, and thus the wet clean process cannot be performed. If the temperature is lower than 200° C., the wet clean process cannot be performed. If the temperature is higher than 360° C., process stability of the wet clean process is not satisfactory. In the dry etching process, if the temperature is lower than 20° C. and/or the plasma power is lower than 120 W, the dry etching process cannot be performed. If the temperature is higher than 75° C. and/or the plasma power is higher than 3500 W, the dry etching process may be performed excessively.

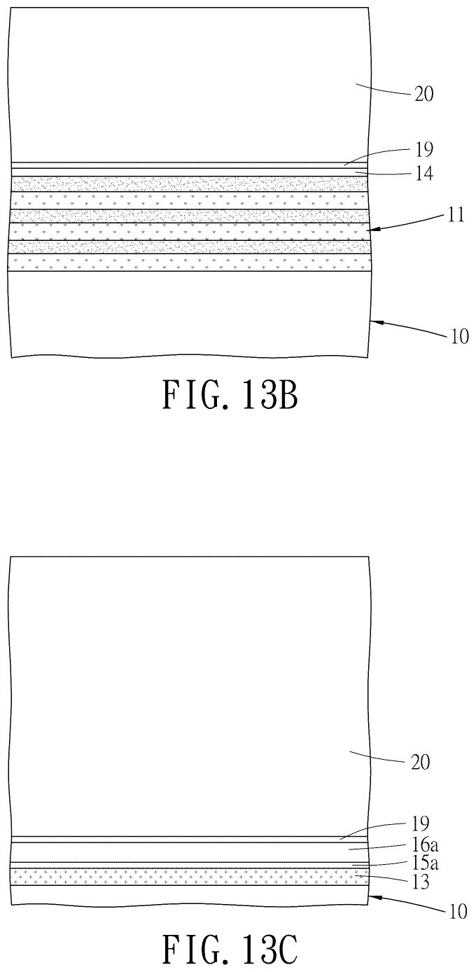

Referring to FIG. 1B and the examples illustrated in FIGS. 13A, 13B, and 13C, the method 100 proceeds to step 12A, where a dummy gate dielectric layer 19 and a dummy gate layer 20 are sequentially formed. FIG. 13B is a schematic view taken along line A-A shown in FIG. 13A, and FIG. 13C is a schematic view taken along line B-B shown in FIG. 13A. The dummy gate dielectric layer 19 is formed on the structure shown in FIGS. 12A and 12B, and the dummy gate layer 20 is then formed on the dummy gate dielectric layer 19. In some embodiments, each of the dummy gate dielectric layer 19 and the dummy gate layer 20 may be formed by a suitable deposition process, for example, but not limited to, CVD, ALD, PVD, PECVD, PEALD, or other suitable deposition processes. Other suitable processes are within the contemplated scope of the present disclosure. In some embodiments, the dummy gate dielectric layer 19 may include silicon oxide. Other suitable materials for forming the dummy gate dielectric layer 19 are within the contemplated scope of the present disclosure. In some embodiments, dummy gate layer 20 may include polysilicon. Other suitable materials for forming the dummy gate layer 20 are within the contemplated scope of the present disclosure.

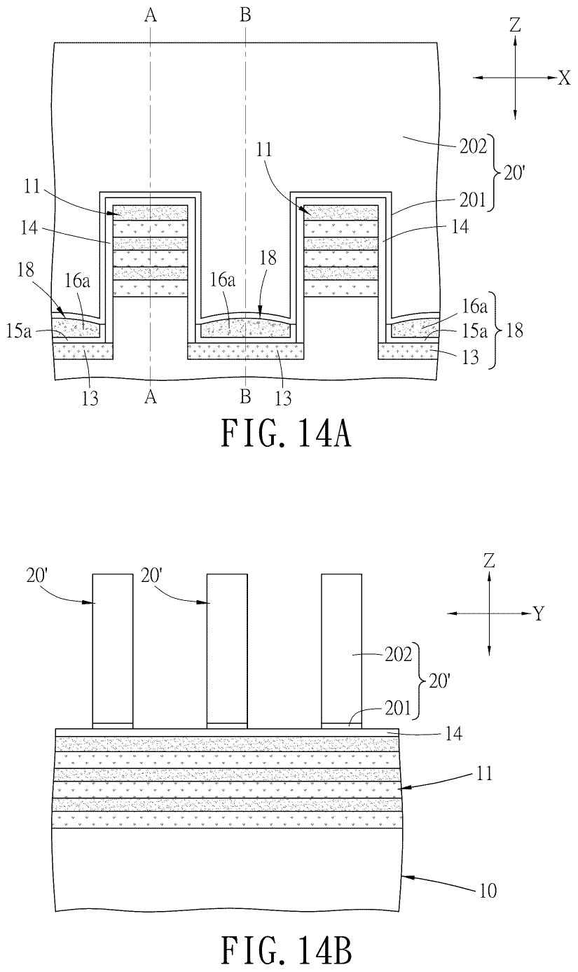

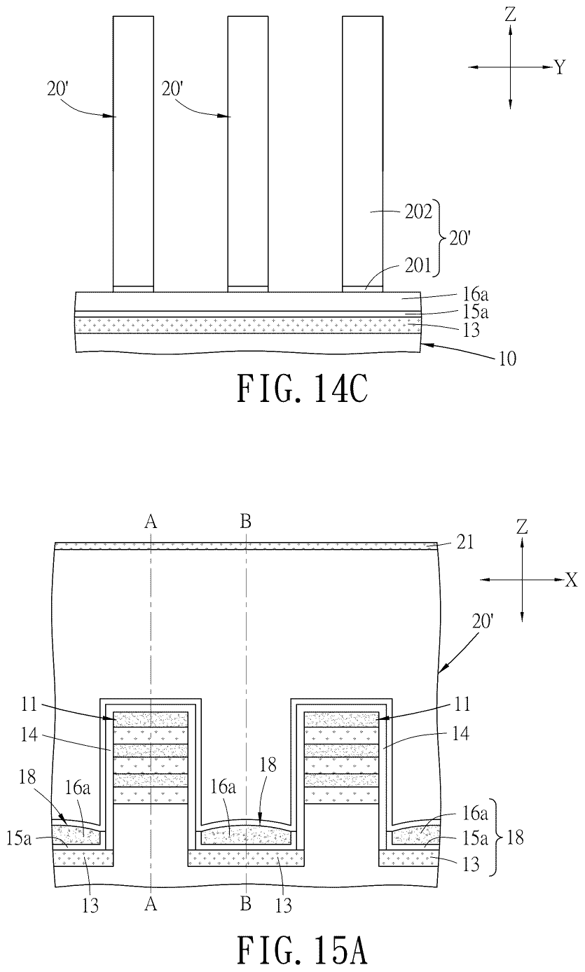

Referring to FIG. 1B and the examples illustrated in FIGS. 14A, 14B, and 14C, the method 100 proceeds to step 13A, where a plurality of dummy gate structures 20′ are formed. FIG. 14B is a schematic view taken along line A-A shown in FIG. 14A, and FIG. 14C is a schematic view taken along line B-B shown in FIG. 14A. The structure shown in FIGS. 13A, 13B, and 13C is patterned by a photolithography process including at least one etching process to form the dummy gate structures 20′. The dummy gate structures 20′ extend in an X direction parallel to a lower surface of the substrate 10, and are spaced apart from one another in a Y direction transverse to the X direction and parallel to the lower surface of the substrate 10. Each of the dummy gate structures 20′ includes a dummy gate dielectric 201 disposed on the cap layers 14 and the isolation structures 18, and a dummy gate 202 disposed on the dummy gate dielectric 201 opposite to the cap layers 14 and the isolation structures 18.

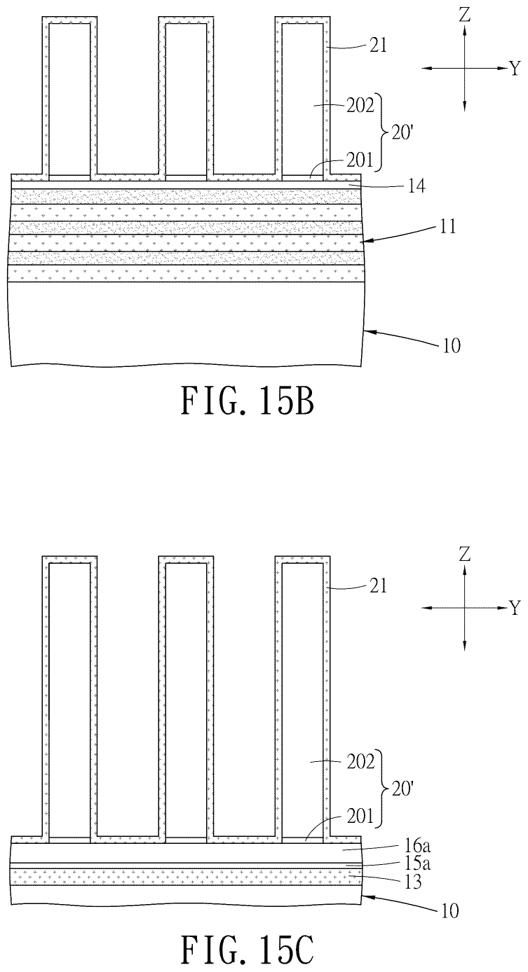

Referring to FIG. 1B and the examples illustrated in FIGS. 15A, 15B, and 15C, the method 100 proceeds to step 14A, where a spacer material layer 21 is formed. FIG. 15B is a schematic view taken along line A-A shown in FIG. 15A, and FIG. 15C is a schematic view taken along line B-B shown in FIG. 15A. The spacer material layer 21 is conformally formed on the structure shown in FIGS. 14A, 14B, and 14C. In some embodiments, the spacer material layer 21 may include, for example, but not limited to, silicon oxide, silicon nitride, silicon carbide, silicon oxycarbide, silicon oxynitride, silicon carbonitride, silicon oxycarbonitride, or combinations thereof. Other suitable materials for forming the spacer material layer 21 are within the contemplated scope of the present disclosure. In some embodiments, the spacer material layer 21 may be formed by a suitable deposition process, for example, but not limited to, CVD, PECVD, PVD, ALD, PEALD, or other suitable deposition processes. Other suitable processes for forming the spacer material layer 21 are within the contemplated scope of the present disclosure.

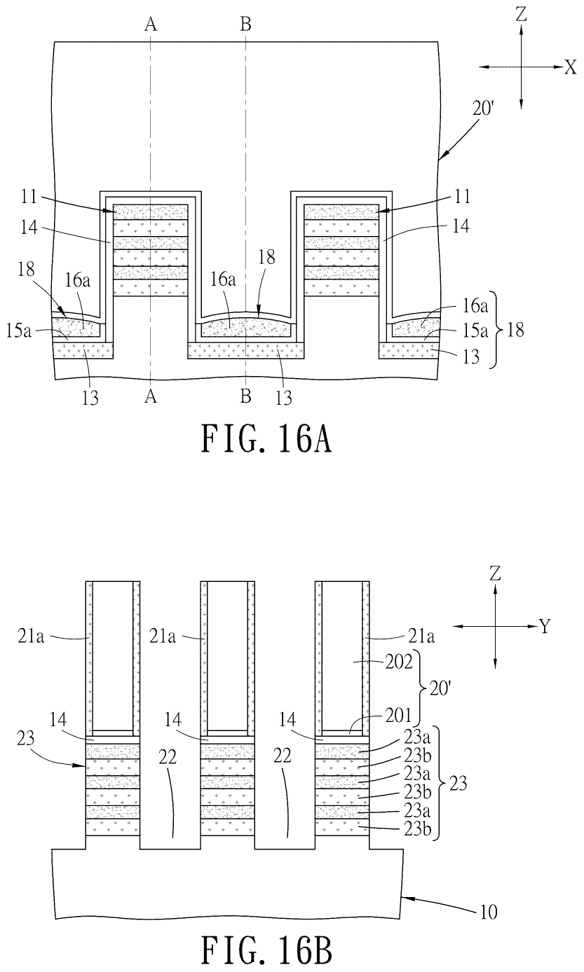

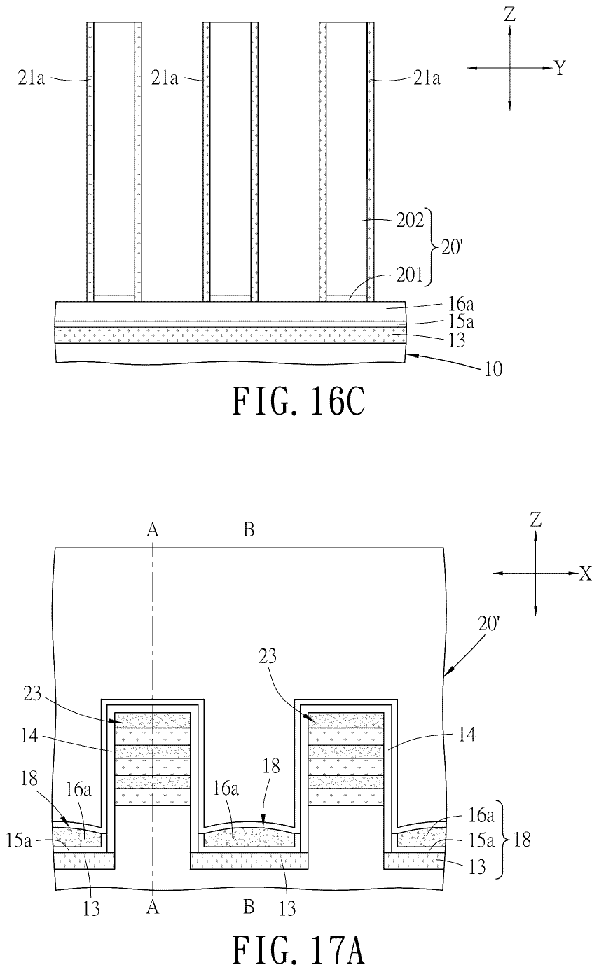

Referring to FIG. 1B and the examples illustrated in FIGS. 16A, 16B, and 16C, the method 100 proceeds to step 15A, where a plurality of dielectric spacers 21a and a plurality of source/drain recesses 22 are formed. FIG. 16B is a schematic view taken along line A-A shown in FIG. 16A, and FIG. 16C is a schematic view taken along line B-B shown in FIG. 16A. The spacer material layer 21 of the structure shown in FIGS. 15A, 15B, and 15C are anisotropically etched such that horizontal portions of the spacer material layer 21 are etched away to form the dielectric spacers 21a. In addition, a photolithography process is conducted so that each of the fin structures 11 is formed into a plurality of the source/drain recesses 22 and a plurality of stacked structures 23. Two adjacent ones of the stacked structures 23 are spaced apart from each other by a corresponding one of the source/drain recesses 22. Each of the stacked structures 23 includes a plurality of channel features 23a and a plurality of sacrificial features 23b disposed to alternate with the channel features 23a in a Z direction transverse to the X direction and the Y direction.

In some embodiments, after the source/drain recesses 22 are formed, a plurality of inner spacers (not shown) may be formed to laterally cover the sacrificial features 23b. Formation of the inner spacers may include: sub-step (i) of laterally recessing the sacrificial feature 23b by an isotropic etching process to remove side portions of the sacrificial features 23b based on a relatively high etching selectivity of the sacrificial features 23b with respect to the channel features 23a, so as to form lateral recesses (not shown); sub-step (ii) of conformally forming an inner spacer material layer (not shown) to cover the substrate 10, the channel features 23a, the cap layers 14, the dummy gate structures 20′, and the dielectric spacers 21a, and to fill the lateral recesses; and sub-step (iii) of isotropically etching the inner spacer material layer to form the inner spacers in the lateral recesses so as to laterally cover the sacrificial features 23b.

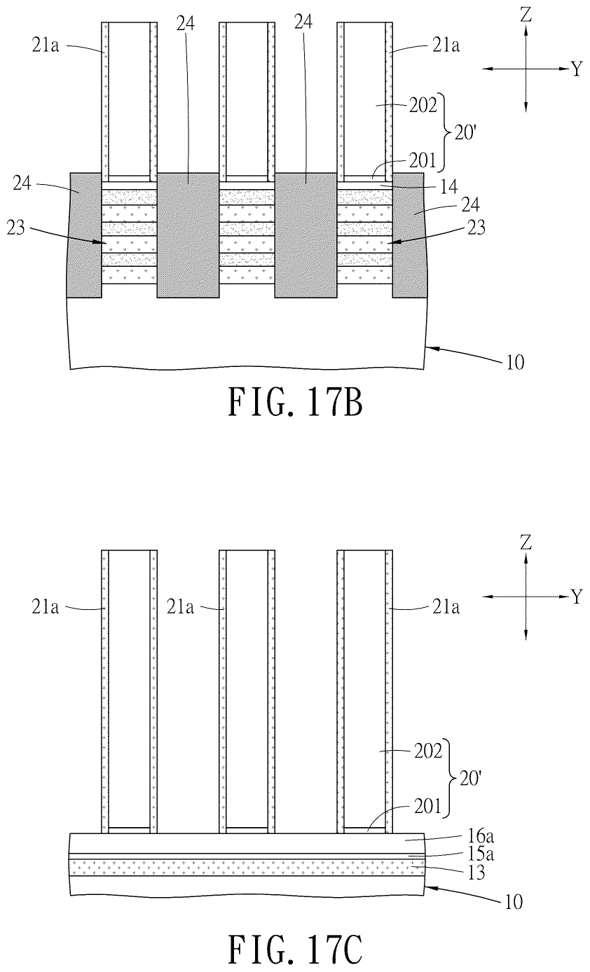

Referring to FIG. 1B and the examples illustrated in FIGS. 17A, 17B, and 17C, the method 100 proceeds to step 16A, where a plurality of source/drain regions 24 are respectively formed in the source/drain recesses 22 (see FIG. 16B). FIG. 17B is a schematic view taken along line A-A shown in FIG. 17A, and FIG. 17C is a schematic view taken along line B-B shown in FIG. 17A. The source/drain regions 24 are formed by growing an epitaxial layer in the source/drain recesses 22 through epitaxial growth. In some embodiments, the technique for the epitaxial growth may include, for example, but not limited to, a low pressure CVD (LPCVD) process, an atomic layer CVD (ALCVD) process, an ultrahigh vacuum CVD (UHVCVD) process, a reduced pressure CVD (RPCVD) process, a molecular beam epitaxy (MBE) process, or a metalorganic vapor phase epitaxy (MOVPE) process. In some embodiments, the technique for the epitaxial growth may include, for example, but not limited to, a cyclic deposition-etch (CDE) epitaxy process or a selective epitaxial growth (SEG) process. The source/drain regions 24 may be doped with germanium (Ge), boron (B), phosphorus (P), or arsenic (As). For example, in some embodiments, the epitaxial layer is grown in the source/drain recesses 22 through an epitaxial growth process with, for example, phosphorus doping when the source/drain regions 24 to be formed are n-FET source/drain regions. In some embodiments, the epitaxial layer is grown in the source/drain recesses 22 through an epitaxial growth process with, for example, geranium doping when the source/drain regions 24 to be formed are p-FET source/drain regions.

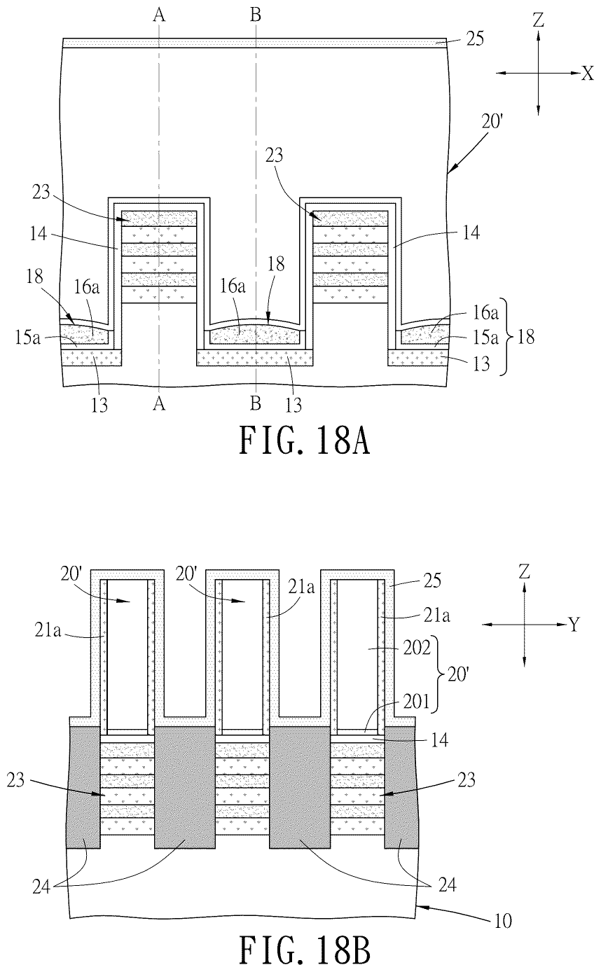

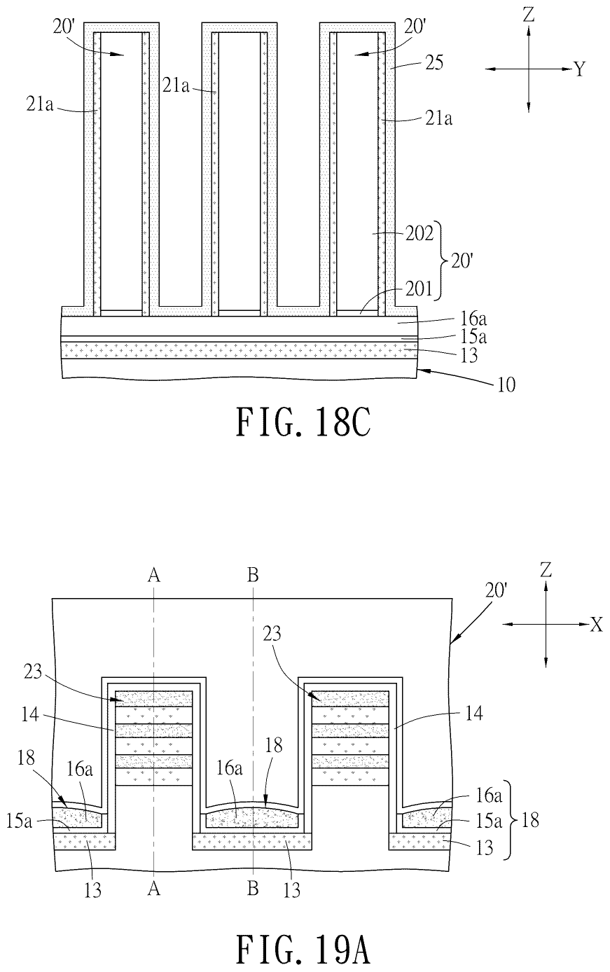

Referring to FIG. 1B and the examples illustrated in FIGS. 18A, 18B, and 18C, the method 100 proceeds to step 17A, where a contact etch stop layer (CESL) 25 is formed. FIG. 18B is a schematic view taken along line A-A shown in FIG. 18A, and FIG. 18C is a schematic view taken along line B-B shown in FIG. 18A. The CESL 25 may be formed on the structure shown in FIGS. 17A, 17B, and 17C by a blanket deposition process, for example, but not limited to, CVD, ALD, or molecular layer deposition (MLD). Other suitable processes for forming the CESL 25 are within the contemplated scope of the present disclosure. In some embodiments, the CESL 25 may include, for example, but not limited to, silicon nitride, carbon-doped silicon nitride, or a combination thereof. Other suitable materials for forming the CESL 25 are within the contemplated scope of the present disclosure.

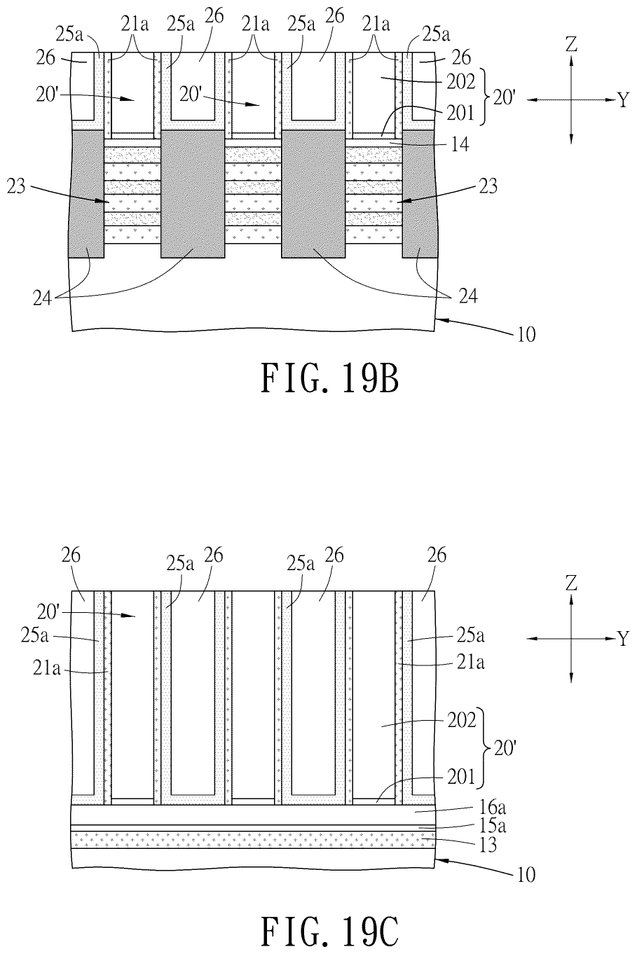

Referring to FIG. 1B and the examples illustrated in FIGS. 19A, 19B, and 19C, the method 100 proceeds to step 18A, where a plurality of contact etch stop features 25a and a plurality of inter-layer dielectric (ILD) features 26 are respectively formed on the source/drain regions 24. FIG. 19B is a schematic view taken along line A-A shown in FIG. 19A, and FIG. 19C is a schematic view taken along line B-B shown in FIG. 19A. A dielectric material layer (not shown) for forming the ILD features 26 is formed on the structure shown in FIGS. 18A, 18B, and 18C by a blanket deposition process, for example, but not limited to, CVD, ALD, or MLD. Other suitable processes for forming the dielectric material layer are within the contemplated scope of the present disclosure. In some embodiments, the dielectric material layer may include, for example, but not limited to, silicon oxide, silicon nitride, silicon oxynitride, or combinations thereof. Other suitable materials for forming the dielectric material layer are within the contemplated scope of the present disclosure. Thereafter, a planarization process is performed to remove an excess portion of the CESL 25, an excess portion of the dielectric material layer, portions of the dielectric spacers 21a, and portions of the dummy gate structures 20′ so as to obtain the contact etch stop features 25a and the ILD features 26. In some embodiments, the planarization process may be, for example, but not limited to, chemical mechanical polishing (CMP). Other suitable planarization processes are within the contemplated scope of the present disclosure.

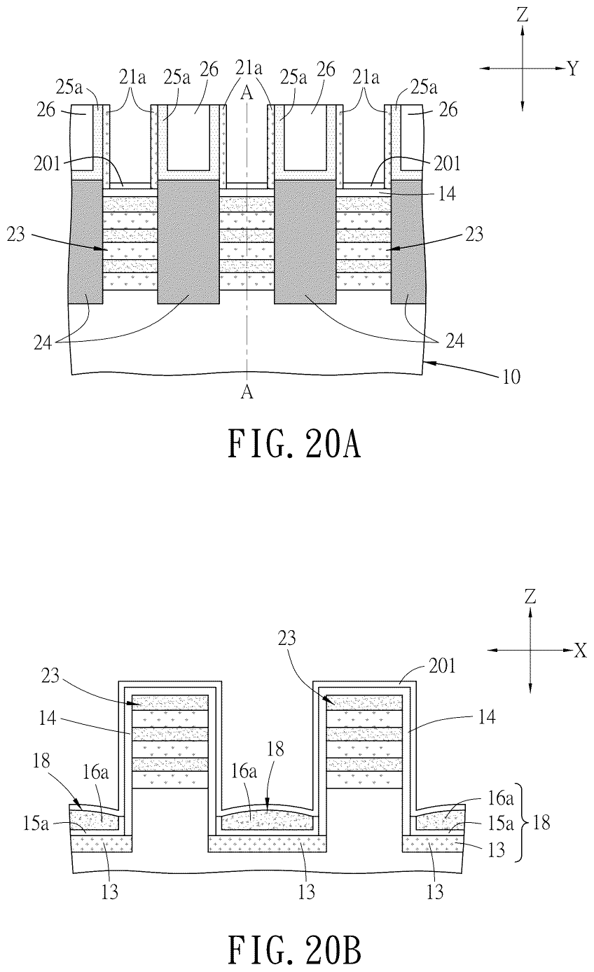

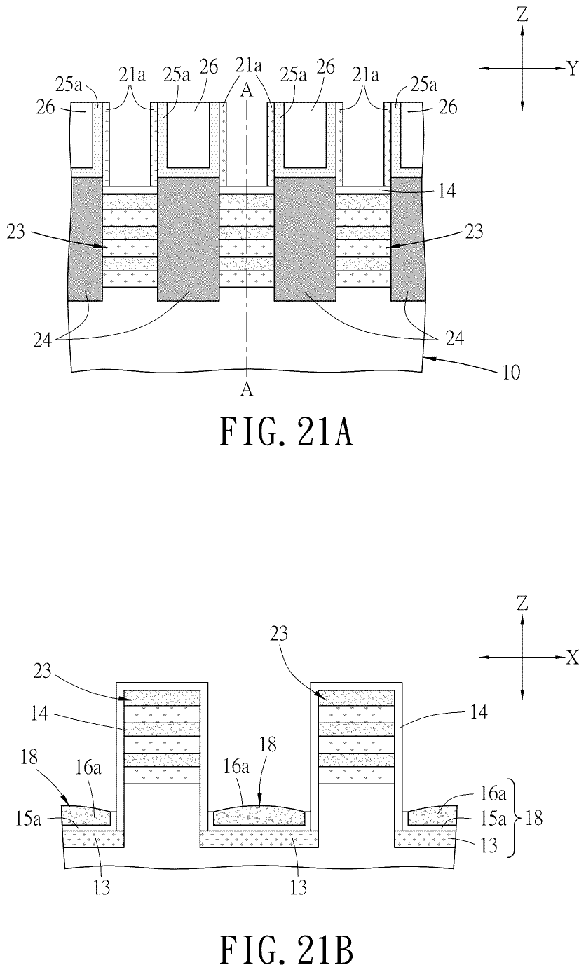

Referring to FIG. 1C and the examples illustrated in FIGS. 20A, 20B, 21A, and 21B, the method 100 proceeds to step 19A, where the dummy gate structures 20′ of the structure shown in FIGS. 19A, 19B, and 19C are removed. FIG. 20B is a schematic view taken along line A-A shown in FIG. 20A, and FIG. 21B is a schematic view taken along line A-A shown in FIG. 21A. In some embodiments, the dummy gate 202 is removed to obtain the structure shown in FIGS. 20A and 20B, and then the dummy gate dielectric 201 of the structure shown in FIGS. 20A and 20B is removed to obtain the structure shown in FIGS. 21A and 21B. The dummy gate structures 20′ may be removed by one or more etching processes. The etching processes may include a wet etching process, a dry etching process, or a combination thereof. Other suitable etching processes are within the contemplated scope of the present disclosure.

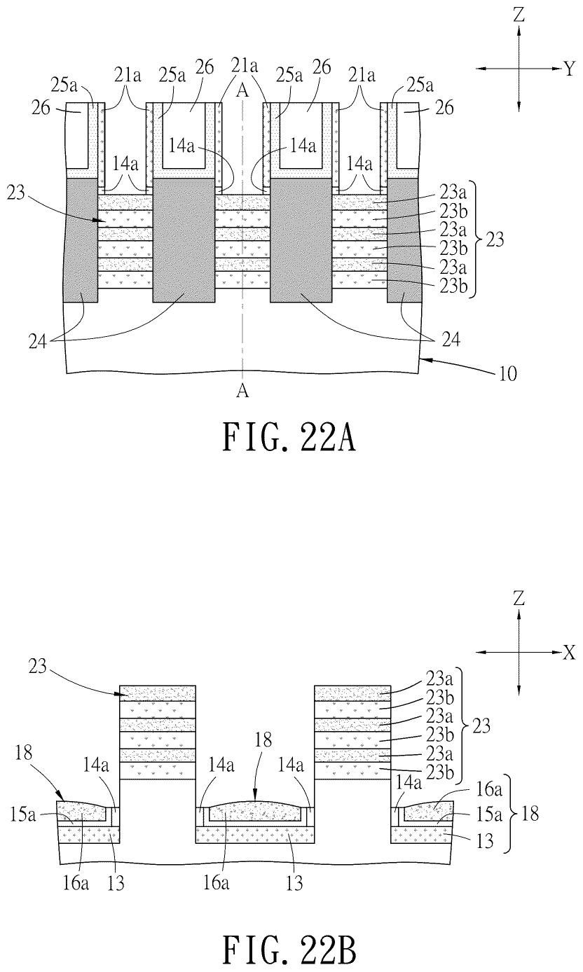

Referring to FIG. 1C and the examples illustrated in FIGS. 22A and 22B, the method 100 proceeds to step 20A, where the cap layers 14 of the structure shown in FIGS. 21A and 21B are partially removed. FIG. 22B is a schematic view taken along line A-A shown in FIG. 22A. Portions of the cap layers 14 exposed from the isolation structures 18 (see FIG. 21B) are removed by a suitable etching process, for example, but not limited to, a breakthrough etching process, so as to form a plurality of spacers 14a. Each of the spacers 14a is disposed between a corresponding one of the isolation structures 18 and a corresponding one of the fin structures 11, and laterally covers the liner 15a of the corresponding one of the isolation structures 18. Other suitable etching processes are within the contemplated scope of the present disclosure.

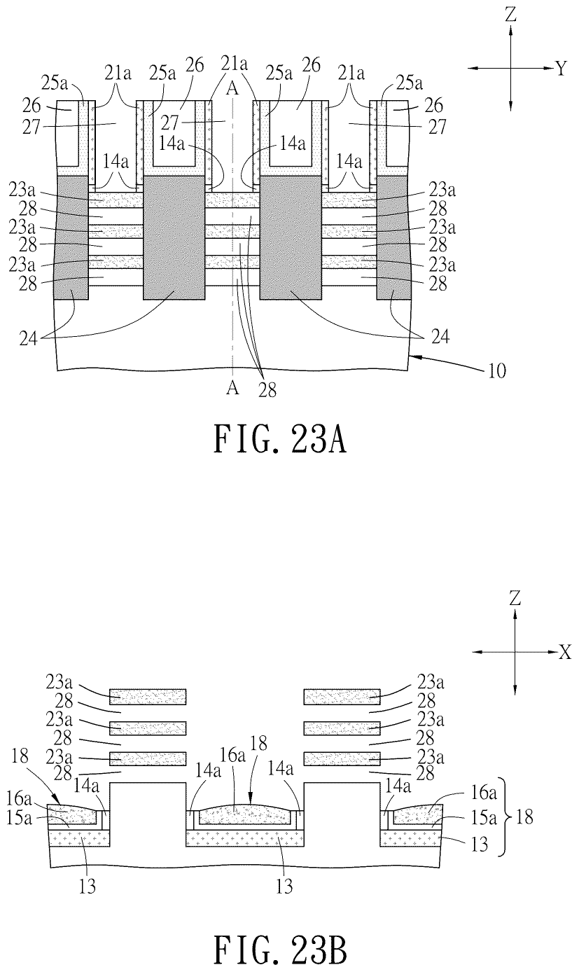

Referring to FIG. 1C and the examples illustrated in FIGS. 23A and 23B, the method 100 proceeds to step 21A, where the sacrificial features 23b of the structure shown in FIGS. 22A and 22B are removed. FIG. 23B is a schematic view taken along line A-A shown in FIG. 23A. In some embodiments, the sacrificial features 23b of the structure shown in FIGS. 22A and 22B may be removed by a suitable etching process, for example, but not limited to, a wet etching process. Other suitable etching processes are within the contemplated scope of the present disclosure. A plurality of first voids 27 and a plurality of second voids 28 are formed in the structure shown in FIGS. 23A and 23B. Each of the first voids 27 is defined by two corresponding ones of the dielectric spacers 21a and an uppermost one of the channel features 23a, and the second voids 28 are formed among the channel features 23a. Since each of the isolation structures 18 is formed with a convex top surface, two opposite edge portions of each of the isolation structures 18 has a height less than that of a center portion (or an uppermost portion) of each of the isolation structures 18, and a risk of the isolation structures 18 blocking a lowermost one of the sacrificial features 23b can be avoided. Therefore, the sacrificial features 23b can be fully removed by the etching process.

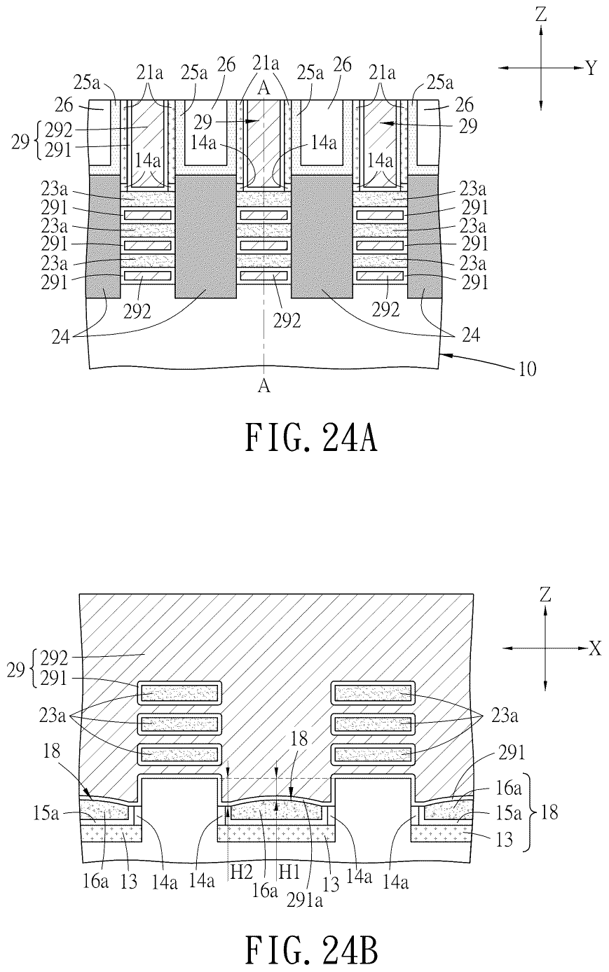

Referring to FIG. 1C and the examples illustrated in FIGS. 24A and 24B, the method 100 proceeds to step 22A, where a plurality of gate dielectric features 291 and a plurality of metal gate features 292 are formed. FIG. 24B is a schematic view taken along line A-A shown in FIG. 24A. The gate dielectric features 291 and the metal gate features 292 are formed in the first voids 27 and the second voids 28 (see FIGS. 23A and 23B). Formation of the gate dielectric features 291 and the metal gate features 292 may include sub-steps (i) and (ii) described hereinafter.

In sub-step (i), a dielectric material layer (not shown) for forming the gate dielectric features 291 and a conductive material layer (not shown) for forming the metal gate features 292 are sequentially formed in the first voids 27 and the second voids 28, and over the dielectric spacers 21a, the contact etch stop features 25a and the ILD features 26. In some embodiments, the dielectric material layer may be made of a high-k material. In some embodiments, the high-k material may be a wide bandgap insulator material with a good thermal stability. In some embodiments, the high-k material may be hafnium oxide, zirconium silicate, magnesium oxide, calcium oxide, aluminum oxide, scandium oxide, or combinations thereof. Other suitable high-k materials for forming the dielectric material film are within the contemplated scope of the present disclosure. In some embodiments, the dielectric material layer may be formed by a suitable deposition process, for example, but not limited to, CVD or ALD. Other suitable processes for forming the dielectric material layer are within the contemplated scope of the present disclosure. In some embodiments, the conductive material layer may include, for example, but not limited to, aluminum, copper, tungsten, cobalt, ruthenium, titanium, tantalum, molybdenum, nickel, platinum, titanium nitride, tungsten carbonitride, or combinations thereof. In some embodiments, the conductive material layer may be made of an N-type metal, a P-type metal, or a combination thereof. Other suitable materials for forming the conductive material layer are within the contemplated scope of the present disclosure. In some embodiments, the conductive material layer may be formed by a suitable deposition process, for example, but not limited to, CVD, PVD, or electroless plating. Other suitable processes for forming the conductive material film are within the contemplated scope of the present disclosure.

In sub-step (ii), a planarization process (e.g., CMP or other suitable planarization processes) is performed to remove an excess portion of the dielectric material layer and an excess portion of the conductive material layer over the dielectric spacers 21a, the contact etch stop features 25a and the ILD features 26, so as to obtain the gate dielectric features 291 and the metal gate features 292. The gate dielectric features 291 and the metal gate features 292 are collectively configured as a plurality of metal gate structures 29. The metal gate structures 29 are spaced apart from each other in the Y direction, and extend in the X direction. As described above, since each of the isolation structures 18 is formed with a convex top surface, the sacrificial features 23b can be fully removed in step 21A. Therefore, current leakage will not occur among the inner metal gate portions of the metal gate features 292, which are disposed alternatively with the channel features 23a.

Referring to the example illustrated in FIG. 24B, each of the isolation structures 18 is conformally covered with a convex gate dielectric portion 291a of a corresponding one of the gate dielectric features 291. A center portion (or an uppermost portion) of the convex top surface of each of the isolation structures 18 and a top surface of the substrate segment 101 define a height (H1) in the Z direction, and an edge portion of the convex top surface of each of the isolation structures 18 and the top surface of the substrate segment 101 define a height (H2) in the Z direction. The height (H2) is greater than the height (H1) by a value ranging from about 2 nm to about 9 nm.

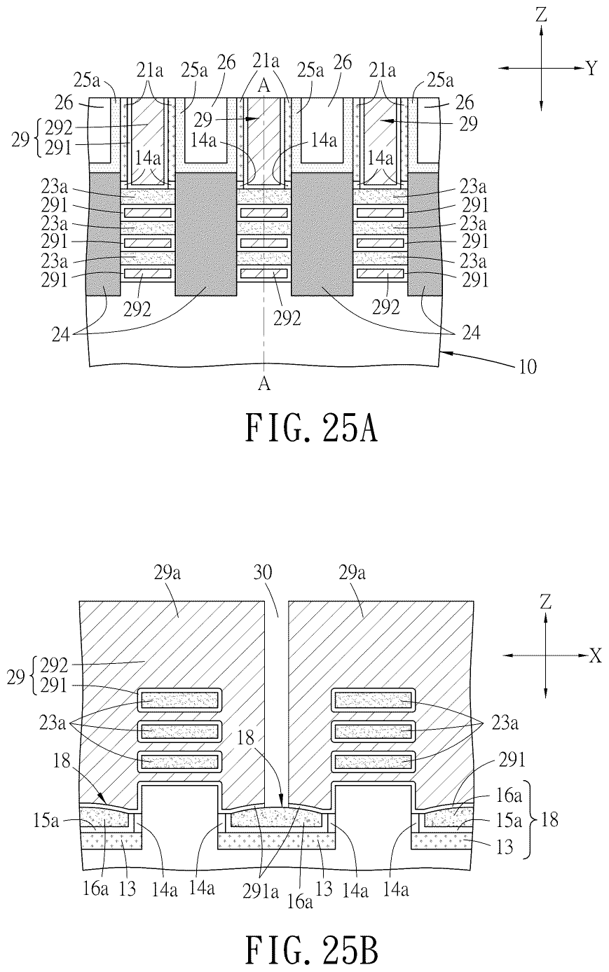

Referring to FIG. 1C and the examples illustrated in FIGS. 25A, 25B, 26A, and 26B, the method 100 proceeds to step 23A, where an isolation feature 31 is formed. The isolation feature 31 is configured to permit two corresponding metal gate portions 29a of a corresponding one of the metal gate structures 29 to be separated from each other by the isolation feature 31. Formation of the isolation feature 31 may include sub-steps (i), (ii), and (iii) described hereinafter.

In sub-step (i), the structure shown in FIGS. 24A and 24B is patterned by a patterning process (for example, but not limited to, a photolithography process) to form a trench 30 (see FIG. 25B), which penetrates a corresponding one of the metal gate features 292 and the convex gate dielectric portion 291a of a corresponding one of the gate dielectric features 291, so as to permit a corresponding one of the isolation structures 18 disposed below the convex gate dielectric portion 291a to be exposed from the trench 30.

In sub-step (ii), a dielectric material layer is formed on the structure shown in FIGS. 25A and 25B, and fills the trench 30. In some embodiments, the dielectric material layer may include, for example, but not limited to, silicon oxide, silicon nitride, silicon carbonitride, silicon oxynitride, silicon carboxynitride, silicon carboxide, hafnium oxide, zirconium oxide, lanthanum oxide, aluminum oxide, or combinations thereof. Other materials for forming the dielectric material layer are within the contemplated scope of the disclosure. In some embodiments, the dielectric layer may be formed by a suitable deposition process, for example, but not limited to, CVD, PVD, ALD, or other suitable deposition processes.

In sub-step (iii), an excess portion of the dielectric layer is removed by a suitable planarization process (e.g., CMP or other suitable planarization processes) to form the isolation feature 31, which penetrates the corresponding one of the metal gate features 292 and the convex gate dielectric portion 291a of the corresponding one of the gate dielectric features 291 to terminate at the corresponding one of the isolation structures 18 so as to be in contact with the isolation portion 16a of the corresponding one of the isolation structures 18. Since the corresponding one of the isolation structures 18 is formed with a convex top surface, the trench 30 is permitted to fully penetrate the corresponding one of the metal gate features 292 and the convex gate dielectric portion 291a of the corresponding one of the gate dielectric features 291, so that the isolation feature 31 thus formed can be in contact with the corresponding one of the isolation structures 18. Therefore, the two corresponding metal gate portions 29a of the corresponding one of the metal gate structures 29 can be fully separated by the isolation feature 31 without current leakage therebetween.

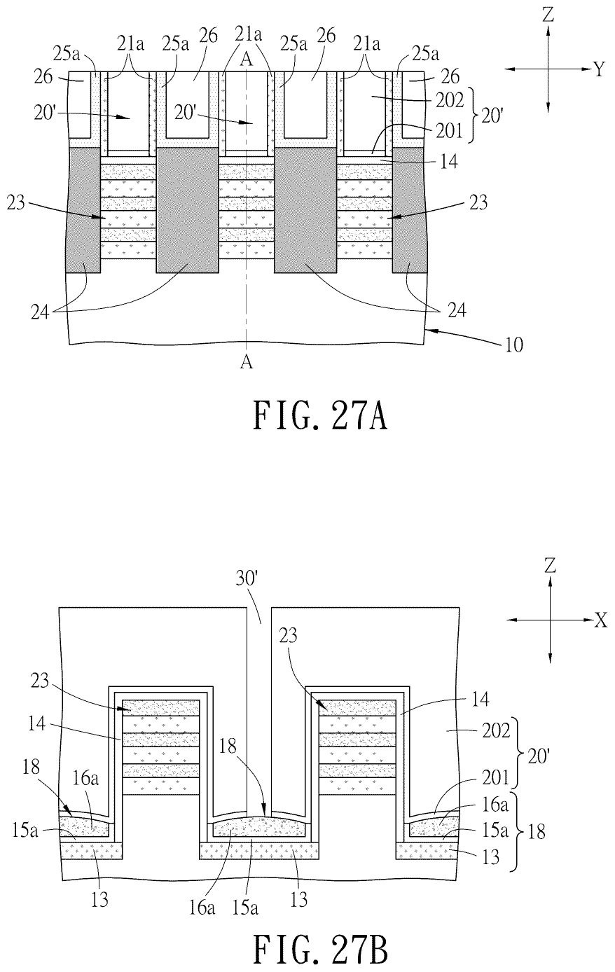

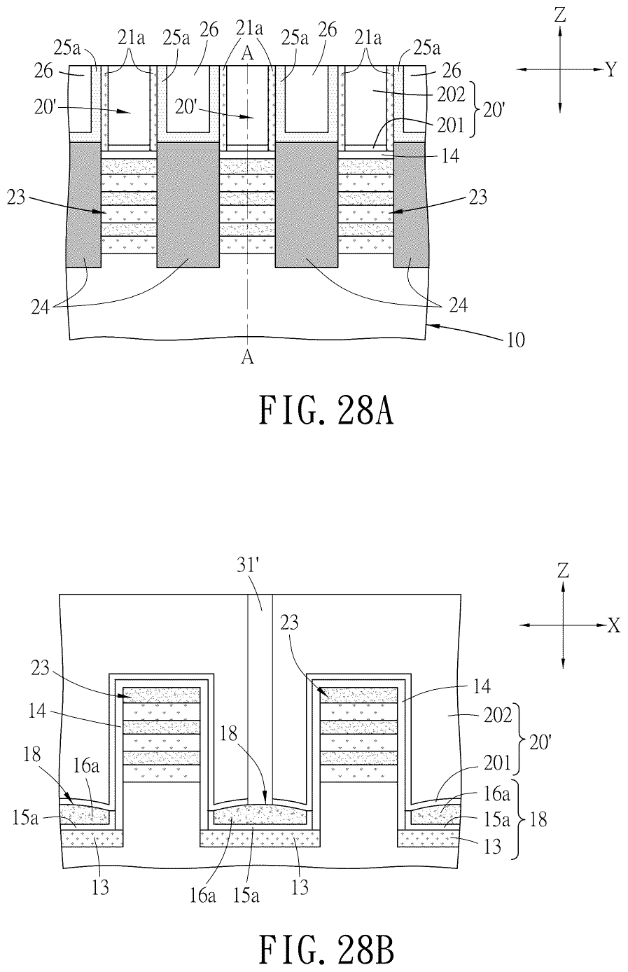

Referring to FIG. 1D and the examples illustrated in FIGS. 27A, 27B, 28A, and 28B, in some embodiments, after completing step 18A (i.e., formation of the contact etch stop features 25a and the ILD features 26 illustrated in FIGS. 19A, 19B and 19C), the method 100 proceeds to step 19B, where an isolation feature 31′ is formed. FIG. 27B is a schematic view taken along line A-A shown in FIG. 27A, and FIG. 28B is a schematic view taken along line A-A shown in FIG. 28A. Formation of the isolation feature 31′ may include: sub-step (i) of forming a trench 30′ (see FIG. 27B), which penetrates the dummy gate 202 and the dummy gate dielectric 201 of a corresponding one of the dummy gate structures 20′, so as to permit a corresponding one of the isolation structures 18 to be exposed from the trench 30′; sub-step (ii) of forming a dielectric material layer on the structure shown in FIGS. 27A and 27B so that the dielectric material layer fills the trench 30′; and sub-step (iii) of removing an excess portion of the dielectric material layer by a suitable planarization process to form the isolation feature 31′. The material and the processes for forming the isolation feature 31′ are similar to those for forming the isolation feature 31 described above in step 23A, and details thereof are omitted for the sake of brevity.

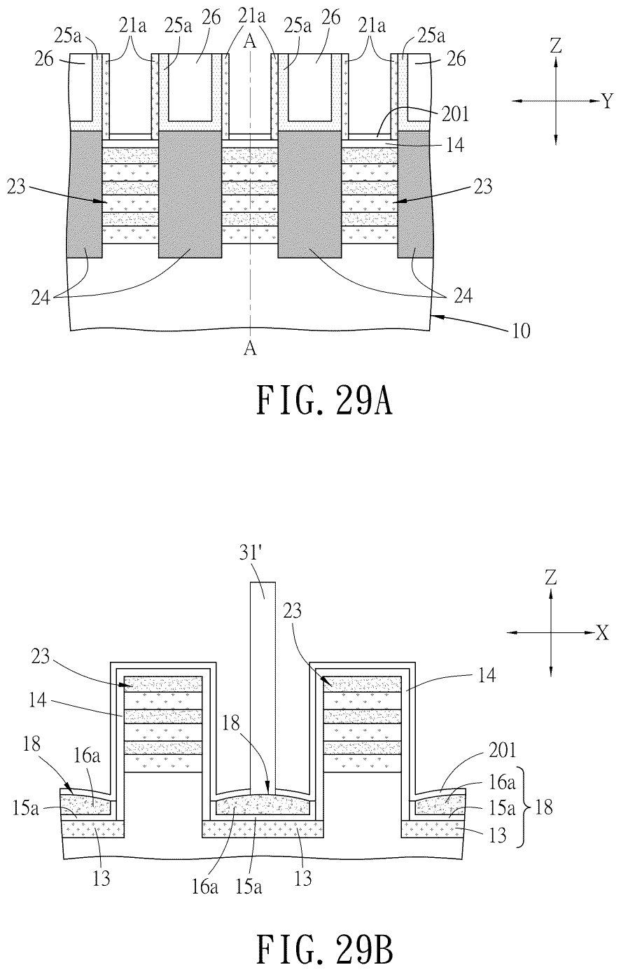

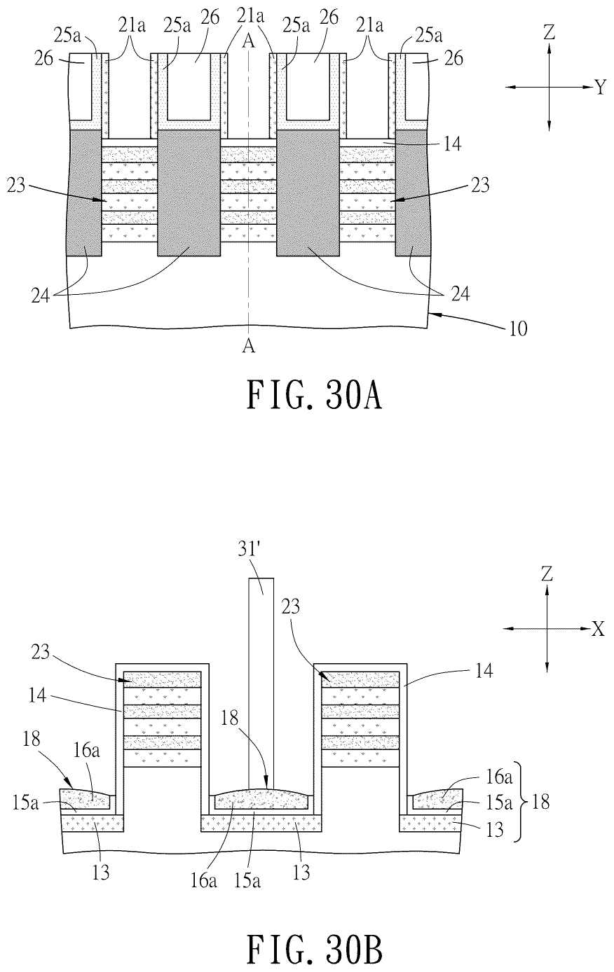

Referring to FIG. 1D and the examples illustrated in FIGS. 29A, 29B, 30A, and 30B, the method 100 proceeds to step 20B, where the dummy gate structures 20′ of the structure shown in FIGS. 28A and 28B are removed. FIG. 29B is a schematic view taken along line A-A of structure shown in FIG. 29A, and FIG. 30B is a schematic view taken along line A-A of structure shown in FIG. 30A. The dummy gate 202 of the structure shown in FIGS. 28A and 28B is removed to obtain the structure shown in FIGS. 29A and 29B, and the dummy gate dielectric 201 of the structure shown in FIGS. 29A and 29B is then removed to obtain the structure shown in FIGS. 30A and 30B. The dummy gate structures 20′ may be removed by one or more etching processes. The etching processes may include a wet etching process, a dry etching process, or a combination thereof. Other suitable etching processes are within the contemplated scope of the present disclosure.

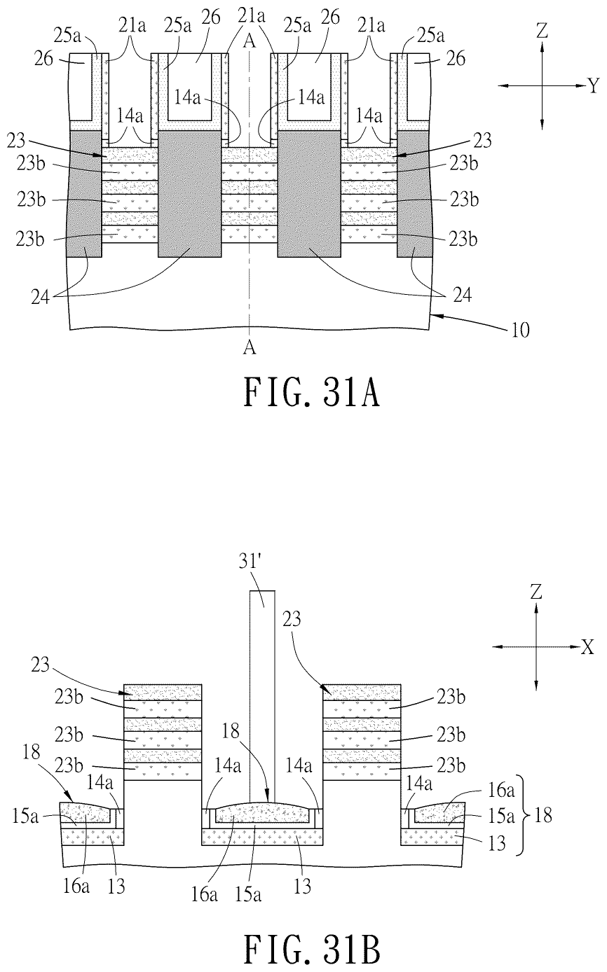

Referring to FIG. 1D and the examples illustrated in FIGS. 31A and 31B, the method 100 proceeds to step 21B, where the cap layers 14 of the structure shown in FIGS. 30A and 30B are partially removed. FIG. 31B is a schematic view taken along line A-A shown in FIG. 31A. Portions of the cap layers 14 exposed from the isolation structures 18 (see FIG. 30B) are removed by a suitable etching process, for example, but not limited to, a breakthrough etching process, so as to form a plurality of the spacers 14a. Other suitable etching processes are within the contemplated scope of the present disclosure.

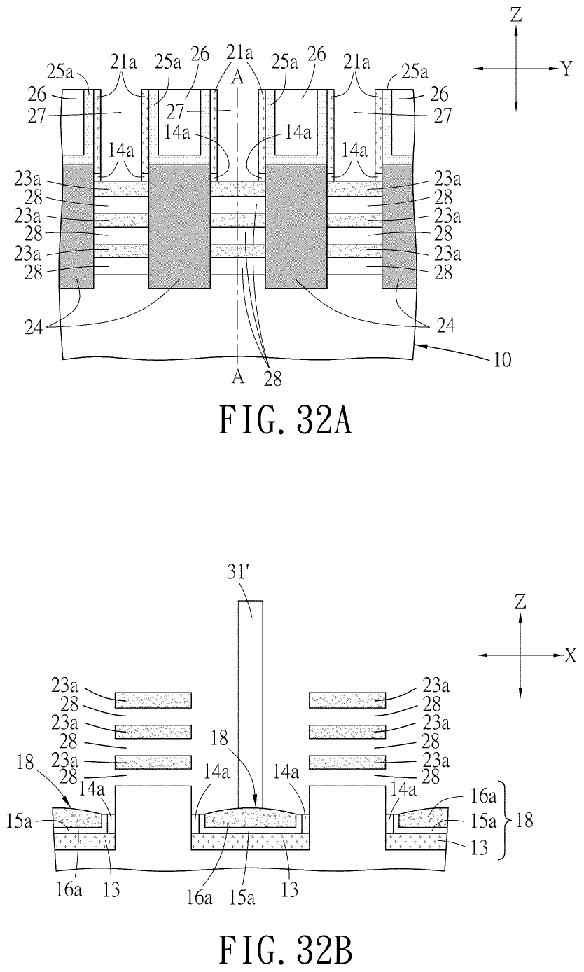

Referring to FIG. 1D and the examples illustrated in FIGS. 32A and 32B, the method 100 proceeds to step 22B, where the sacrificial features 23b of the structure shown in FIGS. 31A and 31B are removed. FIG. 32B is a schematic view taken along line A-A shown in FIG. 32A. In some embodiments, the sacrificial features 23b of the structure shown in FIGS. 31A and 31B may be removed by a suitable etching process, for example, but not limited to, a wet etching process. Other suitable etching processes are within the contemplated scope of the present disclosure. A plurality of the first voids 27 and a plurality of the second voids 28 are formed in the structure shown in FIGS. 32A and 32B. Each of the first voids 27 is formed between two corresponding ones of the dielectric spacers 21a and an uppermost one of the channel features 23a, and the second voids 28 are formed among the channel features 23a. Since each of the isolation structures 18 is formed with a convex top surface, two opposite edge portions of each of the isolation structures 18 have a height less than that of a center portion (or an uppermost portion) of each of the isolation structures 18, and thus a risk of the isolation structures 18 blocking a lowermost one of the sacrificial features 23b can be avoided. Therefore, the sacrificial features 23b can be fully removed by the etching process.

Referring to FIG. 1D and the examples illustrated in FIGS. 33A and 33B, the method 100 proceeds to step 23B, where a plurality of the gate dielectric features 291 and a plurality of the metal gate features 292 are formed. FIG. 33B is a schematic view taken along line A-A shown in FIG. 33A. The gate dielectric features 291 and the metal gate features 292 are formed in the first voids 27 and the second voids 28 (see FIGS. 32A and 32B). The materials and the processes for forming the gate dielectric features 291 and the metal gate features 292 are similar to those described in step 22A above, and thus, details thereof are omitted for the sake of brevity. The semiconductor device 200B is obtained accordingly.

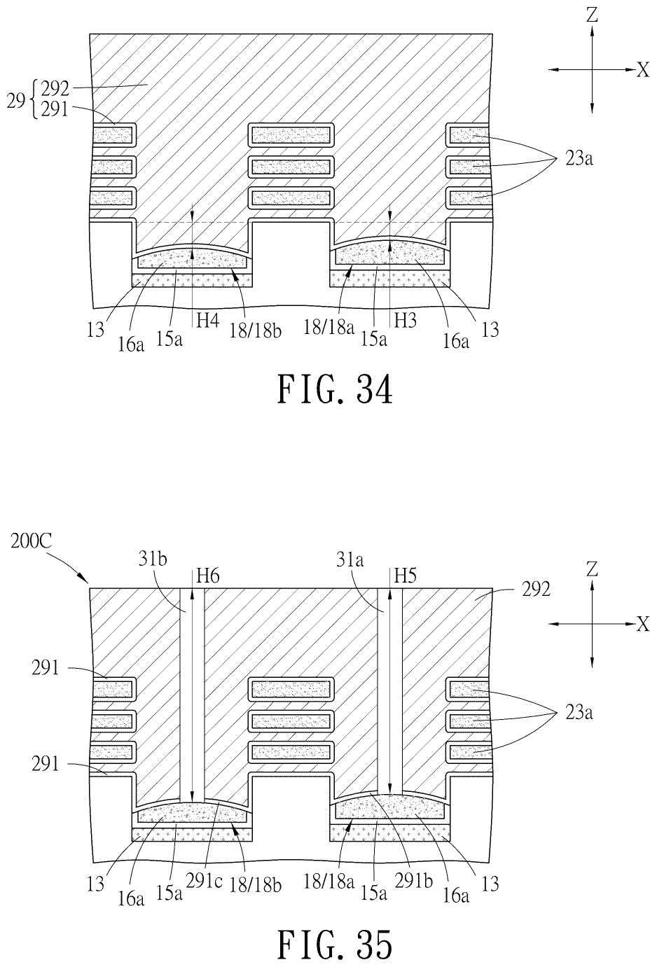

Referring to the example illustrating in FIG. 34, the structure shown in FIG. 34 is similar to the structure shown in FIG. 24B, except that the isolation structures 18 includes the first isolation structure 18a having a convex top surface and the second isolation structure 18b having a convex top surface, that the isolation portion 16a of the first isolation structure 18a has the convex top surface of the first isolation structure 18a and has a first height, and that the isolation portion 16a of the second isolation structure 18b has the convex top surface of the second isolation structure 18b and has a second height less which is less than the first height. A center portion (or an uppermost portion) of the convex top surface of the first isolation structure 18a and a top surface of the substrate segment 101 define a height (H3) in the Z direction, and a center portion (or an uppermost portion) of the convex top surface of the second isolation structure 18b and the top surface of the substrate segment 101 define a height (H4) in the Z direction. The height (H4) is greater than the height (H3) by a value ranging from about 2 nm to about 20 nm.

Similarly, referring to the example shown in FIG. 12E, when the isolation structures 18 includes the third isolation structure 18c formed with a convex top surface and the fourth isolation structure 18d formed with a concave top surface, a height between a center portion (or a lowermost portion) of the concave top surface of the fourth isolation structure 18d and the top surface of the substrate segment 101 in the Z direction is greater than a height between a center portion (or an uppermost portion) of the convex top surface of the third isolation structure 18c and the top surface of the substrate segment 101 in the Z direction by a value ranging from about 2 nm to about 20 nm.

Referring to the example illustrating in FIG. 35, a semiconductor device 200C in accordance with some embodiments is formed from the structure shown in FIG. 34, and includes a first isolation feature 31a and a second isolation feature 31b. The first isolation feature 31a penetrates a corresponding one of the metal gate features 292 and a convex gate dielectric portion 291b of a corresponding one of the gate dielectric features 291 to terminate at the first isolation structure 18a so as to be in contact with the isolation portion 16a of the first isolation structure 18a. The convex gate dielectric portion 291b conformally covers the first isolation structure 18a. The second isolation feature 31b penetrates the corresponding one of the metal gate features 292 and a convex gate dielectric portion 291c of the corresponding one of the gate dielectric features 291 to terminate at the second isolation structure 18b so as to be in contact with the isolation portion 16a of the second isolation structure 18b. The convex gate dielectric portion 291c conformally covers the second isolation structure 18b. A height (H5) of the first isolation feature 31a is less than a height (H6) of the second isolation feature 31b by a value ranging from about 2 nm to about 20 nm.

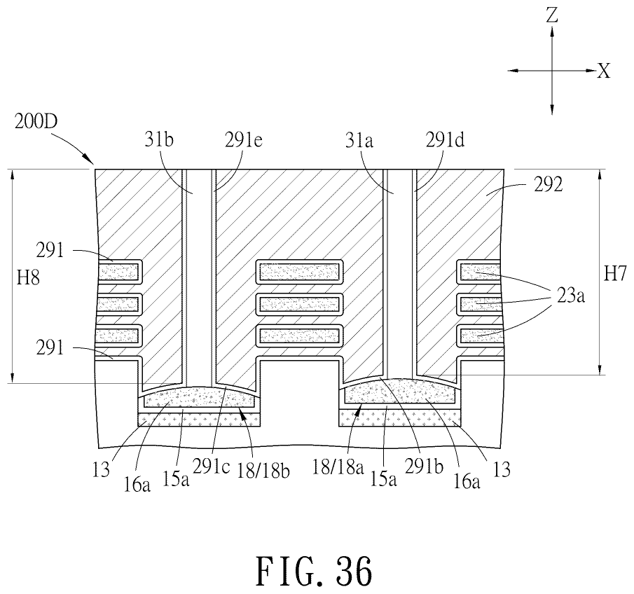

Referring to the example illustrating in FIG. 36, a semiconductor device 200D in accordance with some embodiments has a configuration similar to that of the semiconductor device 200C shown in FIG. 35, except that the isolation feature 31a is laterally covered by a gate dielectric portion 291d of the corresponding one of the gate dielectric features 291, and that the isolation feature 31b is laterally covered by a gate dielectric portion 291e of the corresponding one of the gate dielectric features 291. The gate dielectric portion 291d extends upwardly from the convex gate dielectric portion 291b in the Z direction, and the gate dielectric portion 291e extends upwardly from the convex gate dielectric portion 291c in the Z direction. In the semiconductor device 200D, the height (H5) of the first isolation feature 31a is less than the height (H6) of the second isolation feature 31b by a value ranging from about 2 nm to about 20 nm. In addition, the gate dielectric portion 291d has a height (H7), the gate dielectric portion 291e has a height (H8), and the height (H7) is less than the height (H8) by a value ranging from about 2 nm to about 20 nm.

In this disclosure, an isolation structure to be formed for isolating two corresponding ones of transistors from each other has a convex top surface. A risk of the isolation structure blocking sacrificial features, which will be removed to form a metal gate structure, can be avoided. Therefore, the sacrificial features can be fully removed by an etching process, and current leakage will not occur among inner metal gate portions of the metal gate structure, which are disposed alternatively with channel features.

In accordance with some embodiments of the present disclosure, a semiconductor device includes a substrate, a plurality of first channel features, a plurality of second channel features, and an isolation structure. The plurality of first channel features are spacedly disposed over the substrate in a first direction normal to the substrate. The plurality of second channel features are spacedly disposed over the substrate in the first direction and are spaced apart from the plurality of first channel features in a second direction transverse to the first direction. The isolation structure is disposed between the plurality of first channel features and the plurality of second channel features in the second direction and has a convex top surface.

In accordance with some embodiments of the present disclosure, the isolation structure includes a trench isolation element disposed on the substrate, a liner disposed on the trench isolation element opposite to the substrate, and an isolation portion disposed on the liner opposite to the trench isolation element and having the convex top surface of the isolation structure.

In accordance with some embodiments of the present disclosure, the liner includes a bottom liner portion disposed between the trench isolation element and the isolation portion, and a side liner portion extending from the bottom liner portion to laterally cover the isolation portion.

In accordance with some embodiments of the present disclosure, the trench isolation element is made of a first dielectric material, and the isolation portion is made of a second dielectric material different from the first dielectric material.

In accordance with some embodiments of the present disclosure, the semiconductor device further includes a spacer laterally covering the liner.

In accordance with some embodiments of the present disclosure, the semiconductor device further includes a metal gate structure and an isolation feature. The metal gate structure is disposed on the isolation structure and surrounds the plurality of first channel features and the plurality of second channel features. The isolation feature penetrates the metal gate structure in the first direction, and is in contact with the isolation portion.

In accordance with some embodiments of the present disclosure, the metal gate structure includes a metal gate feature and a gate dielectric feature. The gate dielectric feature includes a first gate dielectric portion conformally covering the isolation portion to separate the metal gate feature from the isolation portion.

In accordance with some embodiments of the present disclosure, the gate dielectric feature further includes a second gate dielectric portion extending from the first gate dielectric portion to laterally cover the isolation feature.

In accordance with some embodiments of the present disclosure, the substrate includes a lower substrate portion, and a first upper substrate portion and a second upper substrate portion which extend from the lower substrate portion in the first direction so that the first upper substrate portion and the second upper substrate portion protrude from the isolation portion, and so that the plurality of first channel features are disposed over the first upper substrate portion and the plurality of second channel features are disposed over the second upper substrate portion. An uppermost portion of the convex top surface of the isolation structure and a top surface of each of the first upper substrate portion and the second upper substrate portion define a first height in the first direction. An edge portion of the convex top surface of the isolation structure and the top surface of each of the first upper substrate portion and the second upper substrate portion define a second height in the first direction. The second height is greater than the first height by a value ranging from about 2 nm to about 9 nm.

In accordance with some embodiments of the present disclosure, a semiconductor device includes a substrate, a first isolation structure, a second isolation structure, and a plurality of channel features. The first isolation structure is disposed on the substrate in a first direction normal to the substrate and has a convex top surface. The second isolation structure is disposed on the substrate in the first direction and is spaced apart from the first isolation structure in a second direction transverse to the first direction. The second isolation structure has a convex top surface or a concave top surface and a height less than a height of the first isolation structure. The plurality of channel features are disposed over the substrate in the first direction and between the first isolation structure and the second isolation structure in a second direction transvers to the first direction.

In accordance with some embodiments of the present disclosure, each of the first isolation structure and the second isolation structure includes a trench isolation element disposed on the substrate, a liner disposed on the trench isolation element opposite to the substrate, and an isolation portion disposed on the liner opposite to the trench isolation element. The isolation portion of the first isolation structure has the convex top surface of the first isolation structure and a height greater than a height of the isolation portion of the second isolation structure. The isolation portion of the second isolation structure has the convex top surface or the concave top surface of the second isolation structure.

In accordance with some embodiments of the present disclosure, the semiconductor device further includes a metal gate structure, a first isolation feature, and a second isolation feature. The metal gate structure is disposed on the first isolation structure and the second isolation structure and surrounds the plurality of channel features. The first isolation feature penetrates the metal gate structure in the first direction, and is in contact with the isolation portion of the first isolation structure. The second isolation feature penetrates the metal gate structure in the first direction, and is in contact with the isolation portion of the second isolation structure.

In accordance with some embodiments of the present disclosure, the metal gate structure includes a metal gate feature and a gate dielectric feature. The gate dielectric feature includes a first gate dielectric portion and a second gate dielectric portion respectively and conformally covering the isolation portion of the first isolation structure and the isolation portion of the second isolation structure so that the metal gate feature is separated from the isolation portion of each of the first isolation structure and the second isolation structure.

In accordance with some embodiments of the present disclosure, the gate dielectric feature further includes a third gate dielectric portion extending from the first gate dielectric portion to laterally cover the first isolation feature, and a fourth gate dielectric portion extending from the second gate dielectric portion to laterally cover the second isolation feature.

In accordance with some embodiments of the present disclosure, the first isolation feature has a first height, the second isolation feature has a second height, and the first height is less than the second height by a value ranging from about 2 nm to about 20 nm.

In accordance with some embodiments of the present disclosure, the third gate dielectric portion has a first height, the fourth gate dielectric portion has a second height, and the first height is less than the second height by a value ranging from about 2 nm to about 20 nm.

In accordance with some embodiments of the present disclosure, the substrate includes a lower substrate portion and an upper substrate portion extending from the lower substrate portion in the first direction so that the upper substrate portion protrudes from the isolation portion of each of the first isolation structure and the second isolation structure and so that the plurality of channel features are disposed over the upper substrate portion. An uppermost portion of the convex top surface of the first isolation structure and a top surface of the upper substrate portion define a first height in the first direction. An uppermost portion of the convex top surface or a lowermost portion of the concave top surface of the second isolation structure and the top surface of the upper substrate portion define a second height in the first direction. The second height is greater than the first height by a value ranging from about 2 nm to about 20 nm.

In accordance with some embodiments of the present disclosure, a method for manufacturing a semiconductor device includes: forming an isolation layer over a substrate to cover a fin structure disposed on the substrate, the isolation layer including a lower isolation portion disposed over substrate, an upper isolation portion disposed over the fin structure, and a lateral isolation portion interconnecting the lower isolation portion and the upper isolation portion and laterally covering the fin structure; forming a dielectric layer to permit the upper isolation portion of the isolation layer to be exposed from the dielectric layer; removing the upper isolation portion of the isolation layer; removing the dielectric layer; and removing the lateral isolation portion of the isolation layer so that the lower isolation portion is formed into an isolation portion having a convex top surface.

In accordance with some embodiments of the present disclosure, the method for manufacturing a semiconductor device further includes, before forming the isolation layer: forming a trench isolation element on the substrate; selectively forming a cap layer to cover the fin structure and to expose the trench isolation element from the cap layer; and conformally forming a liner layer to cover the cap layer and the trench isolation element.

In accordance with some embodiments of the present disclosure, the method for manufacturing a semiconductor device further includes, after forming the isolation portion having the convex top surface: removing a portion of the liner layer to form a liner disposed between the isolation portion and the trench isolation element, so that the trench isolation element, the liner, and the isolation portion are collectively configured as an isolation structure having the convex top surface; and removing a portion of the cap layer to form a spacer laterally covering the liner.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a plurality of first channel features spacedly disposed over the substrate in a first direction normal to the substrate;
a plurality of second channel features spacedly disposed over the substrate in the first direction and spaced apart from the plurality of first channel features in a second direction transverse to the first direction; and
an isolation structure disposed between the plurality of first channel features and the plurality of second channel features in the second direction and having a convex top surface.

2. The semiconductor device as claimed in claim 1, wherein the isolation structure includes a trench isolation element disposed on the substrate, a liner disposed on the trench isolation element opposite to the substrate, and an isolation portion disposed on the liner opposite to the trench isolation element and having the convex top surface of the isolation structure.

3. The semiconductor device as claimed in claim 2, wherein the liner includes a bottom liner portion disposed between the trench isolation element and the isolation portion, and a side liner portion extending from the bottom liner portion to laterally cover the isolation portion.

4. The semiconductor device as claimed in claim 2, wherein the trench isolation element is made of a first dielectric material, and the isolation portion is made of a second dielectric material different from the first dielectric material.

5. The semiconductor device as claimed in claim 3, further comprising a spacer laterally covering the liner.

6. The semiconductor device as claimed in claim 2, further comprising:
a metal gate structure disposed on the isolation structure and surrounding the plurality of first channel features and the plurality of second channel features; and
an isolation feature penetrating the metal gate structure in the first direction, and being in contact with the isolation portion.

7. The semiconductor device as claimed in claim 6, wherein the metal gate structure includes:
a metal gate feature; and
a gate dielectric feature including a first gate dielectric portion conformally covering the isolation portion to separate the metal gate feature from the isolation portion.

8. The semiconductor device as claimed in claim 7, wherein the gate dielectric feature further includes a second gate dielectric portion extending from the first gate dielectric portion to laterally cover the isolation feature.

9. The semiconductor device as claimed in claim 6, wherein
the substrate includes a lower substrate portion, and a first upper substrate portion and a second upper substrate portion which extend from the lower substrate portion in the first direction so that the first upper substrate portion and the second upper substrate portion protrude from the isolation portion and so that the plurality of first channel features are disposed over the first upper substrate portion and the plurality of second channel features are disposed over the second upper substrate portion;
an uppermost portion of the convex top surface of the isolation structure and a top surface of each of the first upper substrate portion and the second upper substrate portion define a first height in the first direction;
an edge portion of the convex top surface of the isolation structure and the top surface of each of the first upper substrate portion and the second substrate portion define a second height in the first direction; and
the second height is greater than the first height by a value ranging from 2 nm to 9 nm.

10. A semiconductor device, comprising:
a substrate;
a first isolation structure disposed on the substrate in a first direction normal to the substrate and having a convex top surface;
a second isolation structure disposed on the substrate in the first direction and spaced apart from the first isolation structure in a second direction transverse to the first direction, the second isolation structure having a convex top surface or a concave top surface and a height less than a height of the first isolation structure; and
a plurality of channel features disposed over the substrate in the first direction and between the first isolation structure and the second isolation structure in a second direction transverse to the first direction.

11. The semiconductor device as claimed in claim 10, wherein each of the first isolation structure and the second isolation structure includes a trench isolation element disposed on the substrate, a liner disposed on the trench isolation element opposite to the substrate, and an isolation portion disposed on the liner opposite to the trench isolation element, the isolation portion of the first isolation structure having the convex top surface of the first isolation structure and a height greater than a height of the isolation portion of the second isolation structure, the isolation portion of the second isolation structure having the convex top surface or the concave top surface of the second isolation structure.

12. The semiconductor device as claimed in claim 11, further comprising:
a metal gate structure disposed on the first isolation structure and the second isolation structure and surrounding the plurality of channel features;
a first isolation feature penetrating the metal gate structure in the first direction, and being in contact with the isolation portion of the first isolation structure; and
a second isolation feature penetrating the metal gate structure in the first direction, and being in contact with the isolation portion of the second isolation structure.

13. The semiconductor device as claimed in claim 12, wherein the metal gate structure includes:
a metal gate feature; and
a gate dielectric feature including a first gate dielectric portion and a second gate dielectric portion respectively and conformally covering the isolation portion of the first isolation structure and the isolation portion of the second isolation structure so that the metal gate feature is separated from the isolation portion of each of the first isolation structure and the second isolation structure.

14. The semiconductor device as claimed in claim 13, wherein the gate dielectric feature further includes a third gate dielectric portion extending from the first gate dielectric portion to laterally cover the first isolation feature, and a fourth gate dielectric portion extending from the second gate dielectric portion to laterally cover the second isolation feature.

15. The semiconductor device as claimed in claim 12, wherein the first isolation feature has a first height, the second isolation feature has a second height, and the first height is less than the second height by a value ranging from 2 nm to 20 nm.

16. The semiconductor device as claimed in claim 14, wherein the third gate dielectric portion has a first height, the fourth gate dielectric portion has a second height, and the first height is less than the second height by a value ranging from 2 nm to 20 nm.

17. The semiconductor device as claimed in claim 14, wherein
the substrate includes a lower substrate portion and an upper substrate portion extending from the lower substrate portion in the first direction so that the upper substrate portion protrudes from the isolation portion of each of the first isolation structure and the second isolation structure and so that the plurality of channel features are disposed over the upper substrate portion;
an uppermost portion of the convex top surface of the first isolation structure and a top surface of the upper substrate portion define a first height in the first direction;
an uppermost portion of the convex top surface or a lowermost portion of the concave top surface of the second isolation structure and the top surface of the upper substrate portion define a second height in the first direction; and
the second height is greater than the first height by a value ranging from 2 nm to 20 nm.

18. A method for manufacturing a semiconductor device, comprising:
forming an isolation layer over a substrate to cover a fin structure disposed on the substrate, the isolation layer including a lower isolation portion disposed over substrate, an upper isolation portion disposed over the fin structure, and a lateral isolation portion interconnecting the lower isolation portion and the upper isolation portion and laterally covering the fin structure;
forming a dielectric layer to permit the upper isolation portion of the isolation layer to be exposed from the dielectric layer;
removing the upper isolation portion of the isolation layer;
removing the dielectric layer; and
removing the lateral isolation portion of the isolation layer so that the lower isolation portion is formed into an isolation portion having a convex top surface.

19. The method as claimed in claim 18, further comprising, before forming the isolation layer:
forming a trench isolation element on the substrate;
selectively forming a cap layer to cover the fin structure and to expose the trench isolation element from the cap layer; and
conformally forming a liner layer to cover the cap layer and the trench isolation element.

20. The method as claimed in claim 18, further comprising, after forming the isolation portion having the convex top surface:
removing a portion of the liner layer to form a liner disposed between the isolation portion and the trench isolation element, so that the trench isolation element, the liner, and the isolation portion are collectively configured as an isolation structure having the convex top surface; and
removing a portion of the cap layer to form a spacer laterally covering the liner.
